(19) United States
(12) Patent Application Publication
(10) Pub. No.: US 2012/0141940 A1
(43) Pub. Date: Jun. 7, 2012

(54) CHEMICALLY AMPLIFIED POSITIVE-TYPE PHOTORESIST COMPOSITION FOR THICK FILM, AND METHOD FOR PRODUCING THICK FILM RESIST PATTERN

(75) Inventors: Takahiro Shimizu, Kawasaki-shi (JP); Yasushi Washio, Kawasaki-shi (JP); Tomoyuki Ando, Kawasaki-shi (JP); Jun Koshiyama, Kawasaki-shi (JP)

(73) Assignee: TOKYO OHKA KOGYO CO., LTD., Kawasaki-shi (JP)

(21) Appl. No.: 13/307,911

(22) Filed: Nov. 30, 2011

(30) Foreign Application Priority Data
Dec. 7, 2010 (JP) 2010-273026
Nov. 9, 2011 (JP) 2011-245494

(51) Int. Cl. G03F 7/20; G03F 7/027

(52) U.S. Cl. 430/285.1; 430/281.1; 430/325

(57) ABSTRACT

A chemically amplified positive-type photoresist composition for a thick film capable of forming a thick film resist pattern having superior resolving ability and controllability of dimensions, and being favorable in rectangularity, as well as a method for producing a thick film resist pattern using such a composition. The photoresist composition comprises an acid generator including a cationic moiety and an anionic moiety, and a resin whose alkali solubility increases by the action of an acid.

This application claims priority to Japanese Patent Application Nos. 2010-273026 and 2011-245494, filed on Dec. 7, 2010 and Nov. 9, 2011, respectively, the contents of which are incorporated herein by reference.

### BACKGROUND OF THE INVENTION

1. Field of the Invention

The present invention relate to a chemically amplified positive-type photoresist composition for a thick film, and method for producing a thick film resist pattern.

2. Related Art

Photofabrication is now the mainstream of a microfabrication technique. Photofabrication is a generic term describing the technology used for manufacturing a wide variety of precision components such as semiconductor packages. The manufacturing is carried out by applying a photoresist composition to the surface of a processing target to form a photoresist layer, patterning this photoresist layer using photolithographic techniques, and then conducting chemical etching, electrolytic etching, and/or electroforming based mainly on electroplating, using the patterned photoresist layer (resist pattern) as a mask.

In recent years, high density packaging technologies have progressed in semiconductor packages along with downsizing electronics devices, and the increase in package density has been developed on the basis of mounting multi-pin thin film in packages, miniaturizing of package size, two-dimensional packaging technologies in flip-tip systems or three-dimensional packaging technologies. In these types of high density packaging techniques, connection terminals, including protruding electrodes (mounting terminals) known as bumps that protrude above the package or metal posts that extend from peripheral terminals on the wafer and connect rewiring with the mounting terminals, are disposed on the surface of the substrate with high precision.

In the photofabrication as described above, a photoresist composition is used, and chemically amplified photoresist compositions containing an acid generator have been known as such a photoresist composition, (see Patent Documents 1, 2 and the like). According to the chemically amplified photoresist composition, an acid is generated from the acid generator upon irradiation with radiation (exposure) and diffusion of the acid is promoted through heat treatment, to cause an acid catalytic reaction with a base resin and the like in the composition resulting in a change to the alkali-solubility of the same.

Also, the photoresist compositions used in the photofabrication described above are typically photoresist compositions for a thick film (see Patent Document 3 and the like). The photoresist compositions for a thick film are employed for forming bumps or metal posts in plating processes, for example. For example, a thick photoresist layer of about 20 μm is formed on a support, and the photoresist layer is exposed through a predetermined mask pattern and then developed to produce a resist pattern in which portions for forming bumps or metal posts are selectively removed (stripped). Then, bumps or metal posts can be formed by embedding a conductor such as copper into the removed portions (resist-free portions) using plating, and then removing the surrounding residual resist pattern.
Patent Document 1: Japanese Unexamined Patent Application, Publication No. H9-176112
Patent Document 2: Japanese Unexamined Patent Application, Publication No. H11-52562
Patent Document 3: Japanese Unexamined Patent Application, Publication No. 2010-185986

### SUMMARY OF THE INVENTION

Hereafter, as the density of semiconductor packages still further increases, further higher density and precision of protruding electrodes and metal posts have been expected. Therefore, when a chemically amplified photoresist composition is to be used as a photoresist composition for a thick film, a chemically amplified-type photoresist composition for a thick film capable of producing a thick film resist pattern having superior resolving ability and controllability of dimensions, and being favorable in rectangularity has been demanded for realizing further higher density and precision of protruding electrodes and metal posts.

However, according to investigations by the present inventors, conventionally known chemically amplified-type photoresist composition for a thick film cannot meet these needs at present. In particular, there exist problems of providing footing profile, i.e., bottom-tailed profile at the resist bottom.

The present invention was made in view of the foregoing problems, and an object of the invention is to provide a chemically amplified positive-type photoresist composition for a thick film capable of producing a thick film resist pattern having superior resolving ability and controllability of dimensions, and being favorable in rectangularity, and to further provide a method for producing a thick film resist pattern using such a composition.

The present inventors elaborately pursued research in order to achieve the object described above. Consequently, it was found that the above described problem can be solved by including a particular acid generator in a chemically amplified positive-type photoresist composition for a thick film, and the present invention has been accomplished. More specifically, the present invention provides the following.

A first aspect of the present invention provides a chemically amplified positive-type photoresist composition for a thick film used for forming on a support a thick photoresist layer, the composition including (A) an acid generator capable of producing an acid upon irradiation with radiation including an electromagnetic wave or particle ray, and (B) a resin whose alkali solubility increases by the action of an acid, in which the acid generator (A) includes a cationic moiety represented by the following general formula (a1):

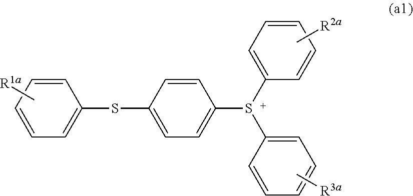

in the formula (a1), R^{1a} to R^{3a} each independently represent a group A selected from the group consisting of an alkoxy group, an alkylcarbonyl group, an alkylcarbonyloxy group and an alkyloxycarbonyl group, or a group in which the group A binds to a bivalent linking group, and an anionic moiety represented by the following general formula (a2):

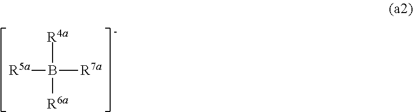

in the formula (a2), R^{4a} to R^{7a} each independently represent a fluorine atom or a phenyl group, and a part or all hydrogen atoms of the phenyl group may be substituted with at least one selected from the group consisting of a fluorine atom and a trifluoromethyl group.

A second aspect of the present invention provides a method for producing a thick film resist pattern, the method including: laminating on a support, a thick photoresist layer having a film thickness of no less than 5 μm constituted with the chemically amplified positive-type photoresist composition for a thick film according to the present invention; exposing by irradiating the thick photoresist layer with radiation including an electromagnetic wave or particle ray; and developing the thick photoresist layer following the exposure to obtain a thick film resist pattern.

According to the present invention, a chemically amplified positive-type photoresist composition for a thick film capable of producing a thick film resist pattern having superior resolving ability and controllability of dimensions, and being favorable in rectangularity, as well as a method for producing a thick film resist pattern using such a composition can be provided.

### DETAILED DESCRIPTION OF THE INVENTION

### Chemically Amplified Positive-Type Photoresist Composition for Thick Film

The chemically amplified positive-type photoresist composition for a thick film according to the present invention (hereinafter, may be merely referred to as “photoresist composition”) contains at least (A) an acid generator capable of producing an acid upon irradiation with radiation including an electromagnetic wave or particle ray, and (B) a resin whose alkali solubility increases by the action of an acid. This photoresist composition is suitably used in manufacture of electronic parts such as circuit substrates and CSPs (chip size package) packaged in circuit substrates, for producing connection terminals such as bumps and metal posts, or wiring patterns. Each component contained in the photoresist composition according to the present invention is described in detail below.

### Acid Generator (A)

The acid generator capable of producing an acid upon irradiation with radiation including an electromagnetic wave or particle ray (A) is, for example, a photo acid generator, and directly or indirectly generates an acid by light. The acid generator (A) includes a cationic moiety and an anionic moiety described in the following.

### [Cationic Moiety]

The cationic moiety included in the acid generator (A) is represented by the following general formula (a1).

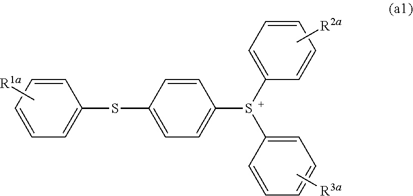

In the general formula (a1), R^{1a} to R^{3a} each independently represent a group A selected from the group consisting of an alkoxy group, an alkylcarbonyl group, an alkylcarbonyloxy group and an alkyloxycarbonyl group, or a group in which the group A binds to a bivalent linking group.

The alkyl moiety of the alkoxy group, alkylcarbonyl group, alkylcarbonyloxy group, and alkyloxycarbonyl group is, for example, a linear or branched alkyl group having 1 to 12 carbon atoms and preferably 1 to 6 carbon atoms, or a cyclic alkyl group having 5 to 12 carbon atoms. In particular, in the case of an alkoxy group, the number of carbon atoms is preferably 1 to 5.

Examples of the linear or branched alkyl group include a methyl group, ethyl group, propyl group, isopropyl group, n-butyl group, isobutyl group, tert-butyl group, pentyl group, isopentyl group, neopentyl group, and the like. Of these, a methyl group is particularly preferred. Also, examples of the cyclic alkyl group include monocycloalkanes such as cyclopentane, cyclohexane, cycloheptane and cyclooctane, and groups derived from polycycloalkanes such as adamantane, norbornane, isobornane and tetracyclododecane by removing one hydrogen atom therefrom, and the like. Among these, a group, which may further have a substituent, derived from adamantane by removing one hydrogen atom therefrom is preferred, and an adamantyl group and a methyladamantyl group are particularly preferred.

Although the bivalent linking group is not particularly limited, those represented by —R^{8a}— or —X—R^{8a}— are preferred. Wherein, R^{8a} represents a bivalent hydrocarbon group, and X represents a hetero atom. Examples of the bivalent hydrocarbon group include alkylene groups having 1 to 4 carbon atoms such as a methylene group and ethylene group; arylene groups having 6 to 12 carbon atoms such as a phenylene group; and combinations of the same. The hetero atom may include an oxygen atom, a sulfur atom, a nitrogen atom and the like, and an oxygen atom and a sulfur atom are preferred.

Although substitution positions of R^{1a} to R^{3a} are not particularly limited, these are preferably each para-position.

Specific examples of preferable cationic moiety represented by the above general formula (a1) include those represented by the following formulae (a1-1) to (a1-10).

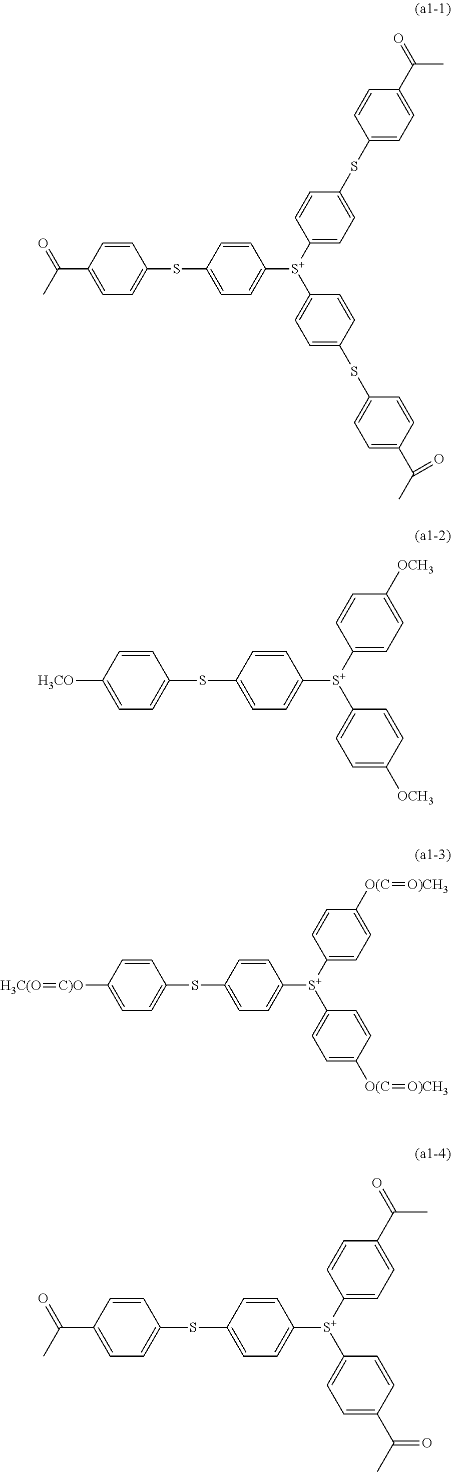

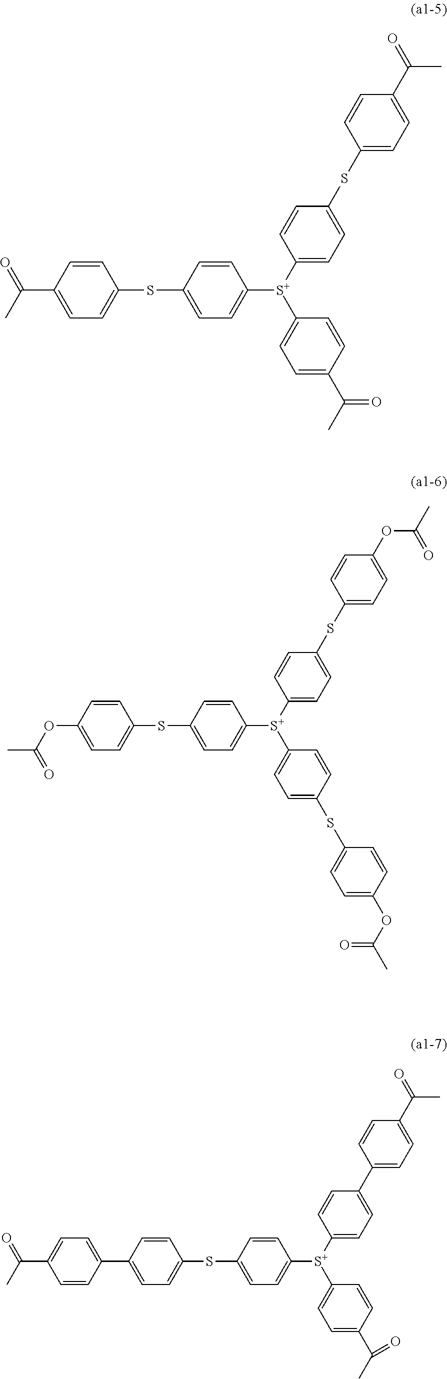

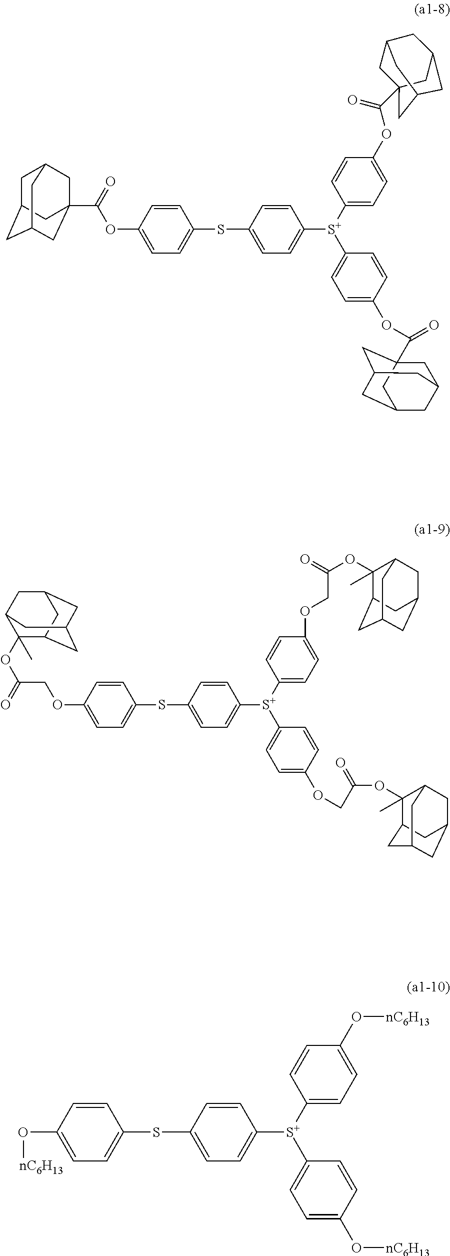

### [Anionic Moiety]

The anionic moiety included in the acid generator (A) is represented by the following general formula (a2).

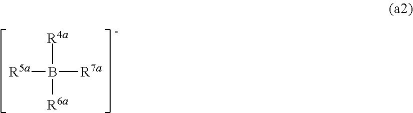

In the above general formula (a2), R^{4a} to R^{7a} each independently represent a fluorine atom or a phenyl group, and a part or all hydrogen atoms of the phenyl group may be substituted with at least one selected from the group consisting of a fluorine atom and a trifluoromethyl group.

Specific examples of preferable anionic moiety include tetrakis(pentafluorophenyl)borate ([B(C₆F₅)₄]⁻), tetrakis[(trifluoromethyl)phenyl]borate ([B(C₆H₄CF₃)₄]⁻), difluorobis(pentafluorophenyl)borate ([(C₆F₅)₂BF₂]⁻), trifluoro(pentafluorophenyl)borate ([(C₆F₅)BF₃]⁻), tetrakis(difluorophenyl)borate ([B(C₆H₃F₂)₄]⁻), and the like. Of these, tetrakis(pentafluorophenyl)borate ([B(C₆F₅)₄]⁻) is particularly preferred.

Since the photoresist composition according to the present invention contains such an acid generator, a thick film resist pattern having superior resolving ability and controllability of dimensions, and being favorable in rectangularity can be produced. One causative of this event is speculated to be uniform dispersion of the acid generator in the thick photoresist layer because of the polar group carried by R^{1a} to R^{3a}.

As the acid generator (A), an acid generator including the cationic moiety represented by the above general formula (a1) and the anionic moiety represented by the above general formula (a2) may be used alone, or two or more thereof may be used in combination. Also, the acid generator (A) may be a combination with an acid generator other the aforementioned acid generator.

Primary examples of the other acid generator include halogen-containing triazine compounds such as 2,4-bis(trichloromethyl)-6-piperonyl-1,3,5-triazine, 2,4-bis(trichloromethyl)-6-[2-(2-furyl)ethenyl]-s-triazine, 2,4-bis(trichloromethyl)-6-[2-(5-methyl-2-furyl)ethenyl]-s-triazine, 2,4-bis(trichloromethyl)-6-[2-(5-ethyl-2-furyl)ethenyl]-s-triazine, 2,4-bis(trichloromethyl)-6-[2-(5-propyl-2-furyl)ethenyl]-s-triazine, 2,4-bis(trichloromethyl)-6-[2-(3,5-dimethoxyphenyl)ethenyl]-s-triazine, 2,4-bis(trichloromethyl)-6-[2-(3,5-diethoxyphenyl)ethenyl]-s-triazine, 2,4-bis(trichloromethyl)-6-[2-(3,5-dipropoxyphenyl)ethenyl]-s-triazine, 2,4-bis(trichloromethyl)-6-[2-(3-methoxy-5-ethoxyphenyl)ethenyl]-s-triazine, 2,4-bis(trichloromethyl)-6-[2-(3-methoxy-5-propoxyphenyl)ethenyl]-s-triazine, 2,4-bis(trichloromethyl)-6-[2-(3,4-methylenedioxyphenyl)ethenyl]-s-triazine, 2,4-bis(trichloromethyl)-6-(3,4-methylenedioxyphenyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl-6-(2-bromo-4-methoxy)styrylphenyl-s-triazine, 2,4-bis-trichloromethyl-6-(3-bromo-4-methoxy)styrylphenyl-s-triazine, 2-(4-methoxyphenyl)-4,6-bis(trichloromethyl)-1,3,5-triazine, 2-(4-methoxynaphthyl)-4,6-bis(trichloromethyl)-1,3,5-triazine, 2-[2-(2-furyl)ethenyl]-4,6-bis(trichloromethyl)-1,3,5-triazine, 2-[2-(5-methyl-2-furyl)ethenyl]-4,6-bis(trichloromethyl)-1,3,5-triazine, 2-[2-(3,5-dimethoxyphenyl)ethenyl]-4,6-bis(trichloromethyl)-1,3,5-triazine, 2-[2-(3,4-dimethoxyphenyl)ethenyl]-4,6-bis(trichloromethyl)-1,3,5-triazine, 2-(3,4-methylenedioxyphenyl)-4,6-bis(trichloromethyl)-1,3,5-triazine, tris(1,3-dibromopropyl)-1,3,5-triazine and tris(2,3-dibromopropyl)-1,3,5-triazine, and halogen-containing triazine compounds represented by the following general formula (a3) such as tris(2,3-dibromopropyl)isocyanurate.

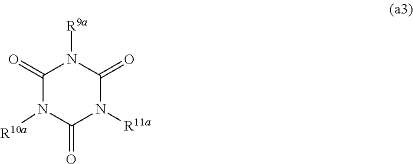

In the above general formula (a3), R^{9a}, R^{10a} and R^{11a} each independently represent a halogenated alkyl group.

Further, secondary examples of other acid generator include α-(p-toluenesulfonyloxyimino)-phenylacetonitrile, α-(benzenesulfonyloxyimino)-2,4-dichlorophenylacetonitrile, α-(benzenesulfonyloxyimino)-2,6-dichlorophenylacetonitrile, α-(2-chlorobenzenesulfonyloxyimino)-4-methoxyphenylacetonitrile and α-(ethylsulfonyloxyimino)-1-cyclopentenylacetonitrile, and compounds represented by the following general formula (a4) having an oximesulfonate group.

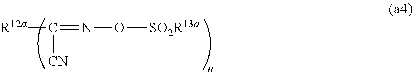

In the above general formula (a4), R^{12a} represents a monovalent, bivalent or trivalent organic group; R^{13a} represents a substituted or unsubstituted saturated hydrocarbon group, an unsaturated hydrocarbon group, or an aromatic compound group; and n represents the number of repeating units of the structure in the parentheses.

In the above general formula (a4), the aromatic compound group indicates a group of compounds having physical and chemical properties characteristic of aromatic compounds, and examples thereof include aryl groups such as a phenyl group and a naphthyl group, and heteroaryl groups such as a furyl group and a thienyl group may be exemplified. These may have one or more appropriate substituents such as halogen atoms, alkyl groups, alkoxy groups and nitro groups on the rings. It is particularly preferable that R^{13a} is an alkyl group having 1 to 6 carbon atoms such as a methyl group, an ethyl group, a propyl group, and a butyl group. In particular, compounds in which R^{12a} represents an aromatic compound group, and R^{13a} represents an alkyl group having 1 to 4 carbon atoms are preferred.

Examples of the acid generator represented by the above general formula (a4), include compounds in which R^{12a} is any one of a phenyl group, a methylphenyl group and a methoxyphenyl group, and R^{13a} is a methyl group, provided that n is 1, and specific examples thereof include α-(methylsulfonyloxyimino)-1-phenylacetonitrile, α-(methylsulfonyloxyimino)-1-(p-methylphenyl)acetonitrile, α-(methylsulfonyloxyimino)-1-(p-methoxyphenyl)acetonitrile, [2-(propylsulfonyloxyimino)-2,3-dihydroxythiophene-3-ylidene](o-tolyl)acetonitrile and the like. Provided that n is 2, the acid generator represented by the above general formula (a4) is specifically an acid generator represented by the following formulae.

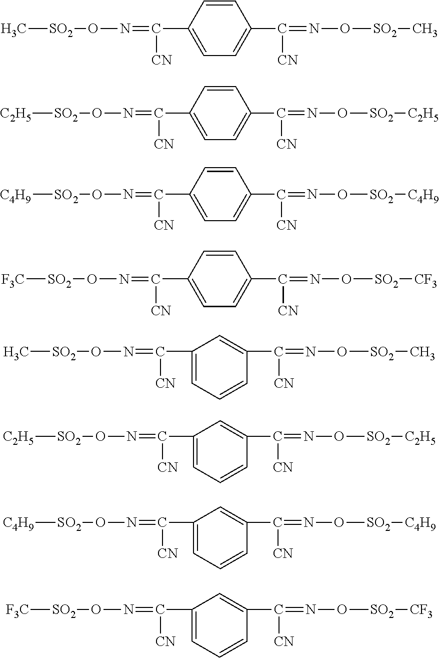

In addition, tertiary examples of the other acid generator include onium salts that have a naphthalene ring at their cation moiety. The expression “have a naphthalene ring” indicates having a structure derived from naphthalene and also indicates at least two ring structures and their aromatic properties are maintained. The naphthalene ring may have a substituent such as a linear or branched alkyl group having 1 to 6 carbon atoms, a hydroxyl group, a linear or branched alkoxy group having 1 to 6 carbon atoms or the like. The structure derived from the naphthalene ring, which may be of a monovalent group (one free valance) or of a bivalent group (two free valences), is desirably of a monovalent group (in this regard, the number of free valance is counted except for the portions connecting with the substituents described above). The number of naphthalene rings is preferably 1 to 3.

Preferably, the cation moiety of the onium salt having a naphthalene ring at the cation moiety is of the structure represented by the following general formula (a5).

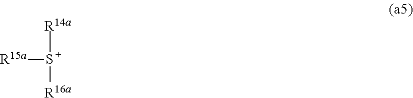

In the above general formula (a5), at least one of R^{14a}, R^{15a} and R^{16a} represents a group represented by the following general formula (a6), and the remaining represents a linear or branched alkyl group having 1 to 6 carbon atoms, a phenyl group which may have a substituent, a hydroxyl group, or a linear or branched alkoxy group having 1 to 6 carbon atoms. Alternatively, one of R^{14a}, R^{15a} and R^{16a} is a group represented by the following general formula (a6), and the remaining two are each independently a linear or branched alkylene group having 1 to 6 carbon atoms, and these terminals may bond to form a ring structure.

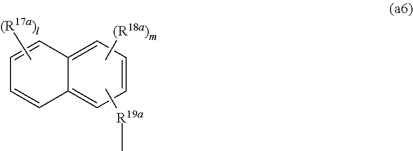

In the above general formula (a6), R^{17a} and R^{18a} each independently represent a hydroxyl group, a linear or branched alkoxy group having 1 to 6 carbon atoms, or a linear or branched alkyl group having 1 to 6 carbon atoms; and R^{19a} represents a single bond or a linear or branched alkylene group having 1 to 6 carbon atoms that may have a substituent. l and m each independently represent an integer of 0 to 2, and l+m is no greater than 3. In this regard, when there exists a plurality of R^{17a}, they may be identical or different from each other. Furthermore, when there exist a plurality of R^{18a}, they may be identical or different from each other.

Preferably, among R^{14a}, R^{15a} and R^{16a} as above, the number of groups represented by the above general formula (a6) is one in view of the stability of the compound, and the remaining are linear or branched alkylene groups having 1 to 6 carbon atoms of which the terminals may bond to form a ring. In this case, the two alkylene groups described above form a 3 to 9 membered ring including sulfur atom(s). Preferably, the number of atoms to form the ring (including sulfur atom(s)) is 5 or 6.

The substituent, which the alkylene group may have, is exemplified by an oxygen atom (in this case, a carbonyl group is formed together with a carbon atom that constitutes the alkylene group), a hydroxyl group or the like.

Alternatively, the substituent, which the phenyl group may have, is exemplified by a hydroxyl group, a linear or branched alkoxy groups having 1 to 6 carbon atoms, linear or branched alkyl groups having 1 to 6 carbon atoms, or the like.

Examples of suitable cation moiety include those represented by the following formulae (a7) and (a8), and the structure represented by the following formula (a8) is particularly preferable.

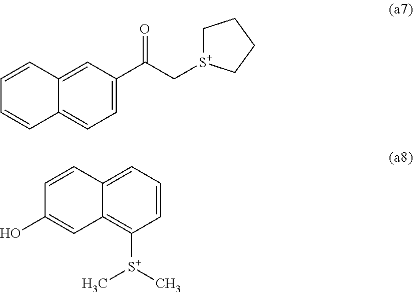

The cation moieties, which may be of an iodonium salt or a sulfonium salt, are desirably of a sulfonium salt in view of acid-producing efficiency.

It is, therefore, desirable that the preferable anion moiety of the onium salt having a naphthalene ring at the cation moiety is an anion capable of forming a sulfonium salt.

The anion moiety of the acid generator is exemplified by fluoroalkylsulfonic acid ions, of which hydrogen atom(s) being partially or entirely fluorinated, or aryl sulfonic acid ions.

The alkyl group of the fluoroalkylsulfonic acid ions may be linear, branched or cyclic and have 1 to 20 carbon atoms. Preferably, the carbon number is 1 to 10 in view of bulkiness and diffusion distance of the produced acid. In particular, branched or cyclic groups are preferable due to shorter diffusion length. Also, methyl, ethyl, propyl, butyl, octyl groups and the like are preferable due to being inexpensively synthesizable.

The aryl group of the aryl sulfonic acid ions may be an aryl group having 6 to 20 carbon atoms, and is exemplified by a phenol group or a naphthyl group that may be unsubstituted or substituted with an alkyl group or a halogen atom. In particular, aryl groups having 6 to 10 carbon atoms are preferred since they can be synthesized inexpensively. Specific examples of preferable aryl group include phenyl, toluenesulfonyl, ethylphenyl, naphthyl, methylnaphthyl groups and the like.

When hydrogen atoms in the fluoroalkylsulfonic acid ion or the aryl sulfonic acid ion are partially or entirely substituted with a fluorine atom, the fluorination rate is preferably 10% to 100%, and more preferably 50% to 100%; it is particularly preferable that all hydrogen atoms are each substituted with a fluorine atom in view of higher acid strength. Specific examples thereof include trifluoromethane sulfonate, perfluorobutane sulfonate, perfluorooctane sulfonate, perfluorobenzene sulfonate, and the like.

Among others, the preferable anion moiety is exemplified by those represented by the following general formula (a9).

R^{20a}SO₃⁻ (a9)

In the above general formula (a9), R^{20a} represents a group represented by the following general formula (a10) or (a11), or a group represented by the following formula (a12).

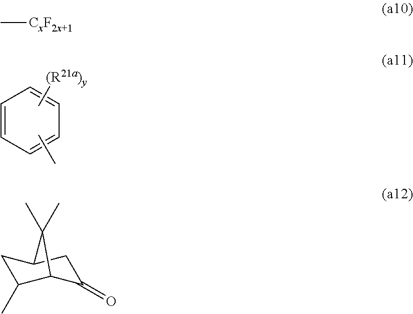

In the above general formula (a10), x represents an integer of 1 to 4. Also, in the above general formula (a11), R^{21a} represents a hydrogen atom, a hydroxyl group, a linear or branched alkyl group having 1 to 6 carbon atoms, or a linear or branched alkoxy group having 1 to 6 carbon atoms; and y represents an integer of 1 to 3. Of these, trifluoromethane sulfonate, and perfluorobutane sulfonate are preferable in view of safety.

In addition, a nitrogen-containing moiety represented by the following general formula (a13) or (a14) may be also be used for the anion moiety.

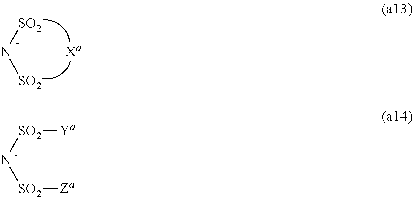

In the above general formulae (a13) and (a14), X^{a} represents a linear or branched alkylene group of which at least one hydrogen atom is substituted with a fluorine atom, the carbon number of the alkylene group is 2 to 6, preferably 3 to 5, and most preferably the carbon number is 3. In addition, Y^{a}, Z^{a} each independently represent a linear or branched alkyl group of which at least one hydrogen atom is substituted with a fluorine atom, the carbon number of the alkyl group is 1 to 10, preferably 1 to 7, and more preferably 1 to 3.

The smaller number of carbon atoms in the alkylene group of X^{a}, or in the alkyl group of Y^{a} or Z^{a} is preferred since the solubility into organic solvent is favorable.

In addition, a larger number of hydrogen atoms each substituted by a fluorine atom in the alkylene group of X^{a}, or in the alkyl group of Y^{a} or Z^{a} is preferred since the acid strength becomes greater. The percentage of fluorine atoms in the alkylene group or alkyl group, i.e., the fluorination rate is preferably 70 to 100% and more preferably 90 to 100%, and most preferable are perfluoroalkylene or perfluoroalkyl groups in which all of the hydrogen atoms are each substituted with a fluorine atom.

Preferable onium salts having a naphthalene ring at their cation moieties are exemplified by compounds represented by the following formulae (a15) and (a16).

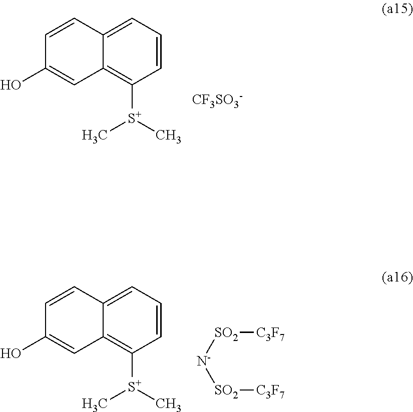

Also, quaternary examples of other acid generator include bissulfonyldiazomethanes such as bis(p-toluenesulfonyl)diazomethane, bis(1,1-dimethyl ethylsulfonyl)diazomethane, bis(cyclohexylsulfonyl)diazomethane and bis(2,4-dimethylphenylsulfonyl)diazomethane; nitrobenzyl derivatives such as 2-nitrobenzyl p-toluenesulfonate, 2,6-dinitrobenzyl p-toluenesulfonate, nitrobenzyl tosylate, dinitrobenzyl tosylate, nitrobenzyl sulfonate, nitrobenzyl carbonate and dinitrobenzyl carbonate; sulfonates such as pyrogalloltrimesylate, pyrogalloltritosylate, benzyltosylate, benzylsulfonate, N-methylsulfonyloxysuccinimide, N-trichloromethylsulfonyloxysuccinimide, N-phenylsulfonyloxymaleimide and N-methylsulfonyloxyphthalimide; trifluoromethane sulfonates such as N-hydroxyphthalimide and N-hydroxynaphthalimide; onium salts such as diphenyliodonium hexafluorophosphate, (4-methoxyphenyl)phenyliodonium trifluoromethanesulfonate, bis(p-tert-butylphenyl)iodonium trifluoromethanesulfonate, triphenylsulfonium hexafluorophosphate, (4-methoxyphenyl)diphenylsulfonium trifluoromethanesulfonate and (p-tert-butylphenyl)diphenylsulfonium trifluoromethanesulfonate; benzointosylates such as benzointosylate and α-methylbenzointosylate; other diphenyliodonium salts, triphenylsulfonium salts, phenyldiazonium salts, benzylcarbonates and the like.

Other acid generators may be preferably a compound represented by the above general formula (a4), and the preferable value of n is 2. Also, R^{12a} is preferably a bivalent substituted or unsubstituted alkylene group having 1 to 8 carbon atoms, or a substituted or unsubstituted aromatic group, while preferable R^{13a} is a substituted or unsubstituted alkyl group having 1 to 8 carbon atoms, or substituted or an unsubstituted aryl group, but not limited thereto.

The ratio of such an other acid generator when used in combination is not particularly limited as long as the advantageous effects of the invention are not inhibited. In general, the other acid generator may be 1 to 300 parts by mass, and preferably 10 to 100 parts by mass with respect to 100 parts by mass of the acid generator including the cationic moiety represented by the above general formula (a1) and the anionic moiety represented by the above general formula (a2).

The content of the acid generator (A) is preferably 0.1 to 10% by mass, and more preferably 0.5 to 3% by mass with respect to total mass of the photoresist composition according to the present invention.

### Resin (B)

The resin (B) whose alkali solubility increases by the action of an acid is not particularly limited, and an arbitrary resin whose alkali solubility increases by the action of an acid may be used. Of these, at least one resin selected from the group consisting of novolak resins (B1), polyhydroxystyrene resins (B2) and acrylic resins (B3) is preferably contained.

### [Novolak Resin (B1)]

As the novolak resin (B1), a resin including the structural unit represented by the following general formula (b1) may be used.

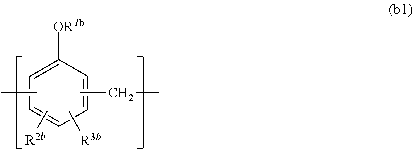

In the above general formula (b1), R^{1b} represents an acid-dissociative dissolution-controlling group; R^{2b} and R^{3b} each independently represent a hydrogen atom or an alkyl group having 1 to 6 carbon atoms.

The acid-dissociative dissolution-controlling group represented by the above R^{1b} is preferably a group represented by the following general formula (b2) or (b3), a linear, branched or cyclic alkyl group having 1 to 6 carbon atoms, a tetrahydropyranyl group, a tetrafuranyl group, or a trialkylsilyl group.

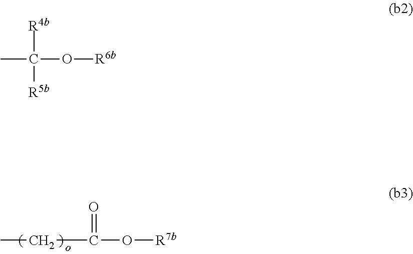

In the above general formulae (b2) and (b3), R^{4b} and R^{5b} each independently represent a hydrogen atom, or a linear or branched alkyl group having 1 to 6 carbon atoms; R^{6b} represents a linear, branched or cyclic alkyl group having 1 to 10 carbon atoms; R^{7b} represents a linear, branched or cyclic alkyl group having 1 to 6 carbon atoms; and o represents 0 or 1.

Examples of the linear or branched alkyl group include a methyl group, an ethyl group, a propyl group, an isopropyl group, a n-butyl group, an isobutyl group, a tert-butyl group, a pentyl group, an isopentyl group, a neopentyl group, and the like. Also, examples of the cyclic alkyl group include a cyclopentyl group, a cyclohexyl group, and the like.

Specific examples of the acid-dissociative dissolution-controlling group represented by the above general formula (b2) include a methoxyethyl group, ethoxyethyl group, n-propoxyethyl group, isopropoxyethyl group, n-butoxyethyl group, isobutoxyethyl group, tert-butoxyethyl group, cyclohexyloxyethyl group, methoxypropyl group, ethoxypropyl group, 1-methoxy-1-methyl-ethyl group, 1-ethoxy-1-methylethyl group, and the like. Furthermore, specific examples of the acid-dissociative dissolution-controlling group represented by the above general formula (b3) include a tert-butoxycarbonyl group, tert-butoxycarbonylmethyl group, and the like. Examples of the trialkylsilyl group include a trimethylsilyl group and tri-tert-butyldimethylsilyl group in which each alkyl group has 1 to 6 carbon atoms.

### [Polyhydroxystyrene Resin (B2)]

As the polyhydroxystyrene resin (B2), a resin including the structural unit represented by the following general formula (b4) may be used.

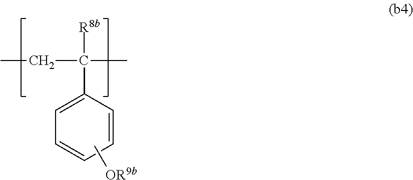

In the above general formula (b4), R^{8b} represents a hydrogen atom or an alkyl group having 1 to 6 carbon atoms; and R^{9b} represents an acid-dissociative dissolution-controlling group.

The alkyl group having 1 to 6 carbon atoms may include, for example, linear, branched or cyclic alkyl groups having 1 to 6 carbon atoms. Examples of the linear or branched alkyl group include a methyl group, ethyl group, propyl group, isopropyl group, n-butyl group, isobutyl group, tert-butyl group, pentyl group, isopentyl group and neopentyl group; and examples of the cyclic alkyl group include a cyclopentyl group and cyclohexyl group.

The acid-dissociative dissolution-controlling group represented by the above R^{9b} may be similar to the acid-dissociative dissolution-controlling groups exemplified in terms of the above general formulae (b2) and (b3).

Furthermore, the polyhydroxystyrene resin (B2) may include another polymerizable compound as a structural unit in order to moderately control physical or chemical properties. The polymerizable compound is exemplified by conventional radical polymerizable compounds and anion polymerizable compounds. Examples of the polymerizable compound include monocarboxylic acids such as acrylic acid, methacrylic acid and crotonic acid; dicarboxylic acids such as maleic acid, fumaric acid and itaconic acid; methacrylic acid derivatives having a carboxyl group and an ester bond such as 2-methacryloyloxyethyl succinic acid, 2-methacryloyloxyethyl maleic acid 2-methacryloyloxyethyl phthalic acid and 2-methacryloyloxyethyl hexahydrophthalic acid; (meth)acrylic acid alkyl esters such as methyl(meth)acrylate, ethyl(meth)acrylate and butyl(meth)acrylate; (meth)acrylic acid hydroxyalkyl esters such as 2-hydroxyethyl(meth)acrylate and 2-hydroxypropyl(meth)acrylate; (meth)acrylic acid aryl esters such as phenyl(meth)acrylate and benzyl(meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; and amide bond-containing polymerizable compounds such as acrylamide and methacrylamide.

### [Acrylic Resin (B3)]

As the acrylic resin (B3), a resin including a structural unit represented by the following general formulae (b5) to (b7) may be used.

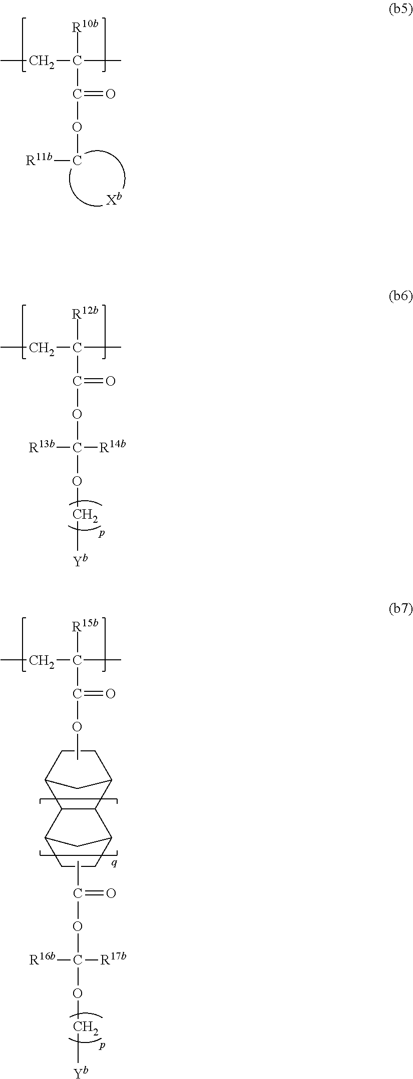

In the above general formulae (b5) to (b7), R^{10b} to R^{17b} each independently represent a hydrogen atom, a linear or branched alkyl group having 1 to 6 carbon atoms, a fluorine atom, or a linear or branched fluorinated alkyl group having 1 to 6 carbon atoms (in which, R^{11b} is not a hydrogen atom); X^{b} and the neighboring carbon atoms form a hydrocarbon ring having 5 to 20 carbon atoms; Y^{b} represents an alicyclic group or alkyl group that may have a substituent; p represents an integer of 0 to 4; and q represents 0 or 1.

Examples of the linear or branched alkyl group include a methyl group, ethyl group, propyl group, isopropyl group, n-butyl group, isobutyl group, tert-butyl group, pentyl group, isopentyl group, neopentyl group, and the like. The fluorinated alkyl group refers to the abovementioned alkyl groups of which the hydrogen atoms are partially or entirely substituted with fluorine atoms.

Preferably, the aforementioned R^{11b} is a linear or branched alkyl group having 2 to 4 carbon atoms in view of higher contrast, proper resolution, and depth and width of focus, etc.; and preferably, R^{13b}, R^{14b}, R^{16b}, R^{17b} are each a hydrogen atom or a methyl group.

The aforementioned X^{b} and the neighboring carbon atoms form an alicyclic group having 5 to 20 carbon atoms. Specific examples of the alicyclic group are the groups of monocycloalkanes and polycycloalkanes such as bicycloalkanes, tricycloalkanes and tetracycloalkanes from which at least one hydrogen atom is removed. Specific examples thereof are monocycloalkanes such as cyclopentane, cyclohexane, cycloheptane and cyclooctane and polycycloalkanes such as adamantane, norbornane, isobornane, tricyclodecane and tetracyclododecane from which at least one hydrogen atom is removed. Particularly preferable are cyclohexane and adamantane from which at least one hydrogen atom is removed (that may further have a substituent).

When the alicyclic group of the abovementioned X^{b} has a substituent on the ring skeleton, the substituent is exemplified by polar groups such as a hydroxide group, carboxyl group, cyano group and oxygen atom (═O), and linear or branched lower alkyl groups having 1 to 4 carbon atoms. The polar group is preferably an oxygen atom (═O) in particular.

The aforementioned Y^{b} is an alicyclic group or an alkyl group; and examples thereof are monocycloalkanes and polycycloalkanes such as bicycloalkanes, tricycloalkanes and tetracycloalkanes from which at least one hydrogen atom is removed. Specific examples thereof are monocycloalkanes such as cyclopentane, cyclohexane, cycloheptane and cyclooctane, and polycycloalkanes such as adamantane, norbornane, isobornane, tricyclodecane and tetracyclododecane, from which at least one hydrogen atom is removed. Particularly preferable is adamantane from which at least one hydrogen atom is removed (that may further have a substituent).

When the alicyclic group of the abovementioned Y^{b} has a substituent on the ring skeleton, the substituent is exemplified by polar groups such as a hydroxide group, carboxyl group, cyano group and oxygen atom (═O), and linear or branched lower alkyl groups having 1 to 4 carbon atoms. The polar group is preferably an oxygen atom (═O) in particular.

When Y^{b} is an alkyl group, it is preferably a linear or branched alkyl group having 1 to 20 carbon atoms, and more preferably 6 to 15 carbon atoms. Preferably, the alkyl group is an alkoxyalkyl group in particular; and examples of the alkoxyalkyl group include a 1-methoxyethyl group, 1-ethoxyethyl group, 1-n-propoxyethyl group, 1-isopropoxyethyl group, 1-n-butoxyethyl group, 1-isobutoxyethyl group, 1-tert-butoxyethyl group, 1-methoxypropyl group, 1-ethoxypropyl group, 1-methoxy-1-methylethyl group, 1-ethoxy-1-methylethyl group, and the like.

Preferable specific examples of the structural unit represented by the above general formula (b5) are those represented by the following formulae (b5-1) to (b5-33).

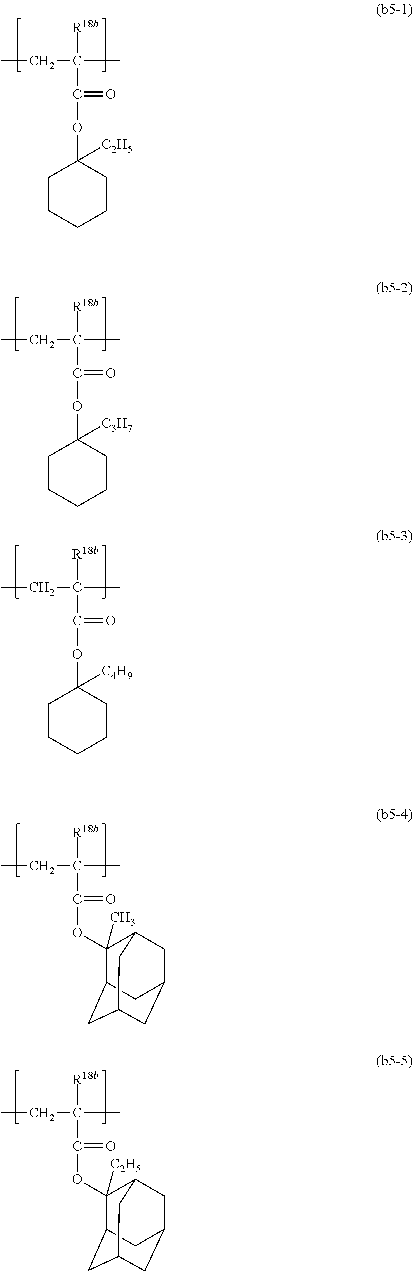

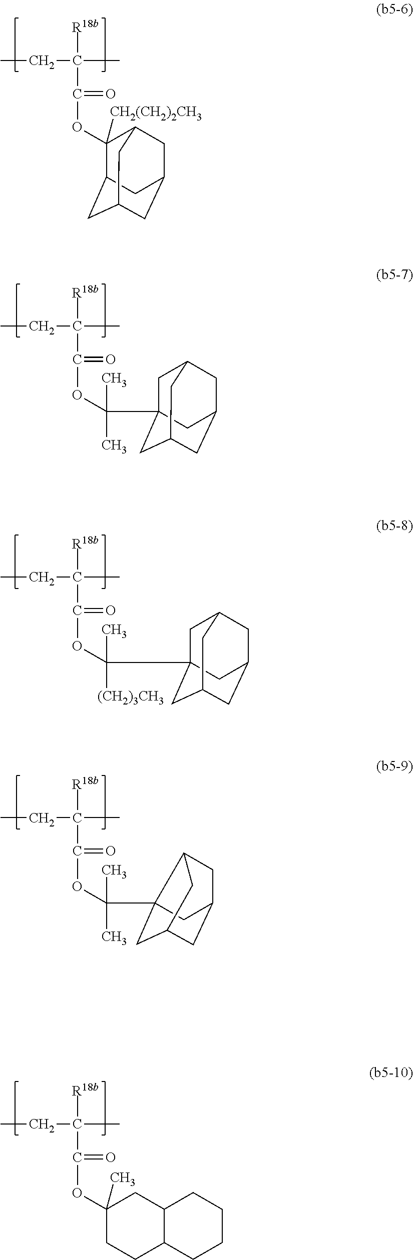

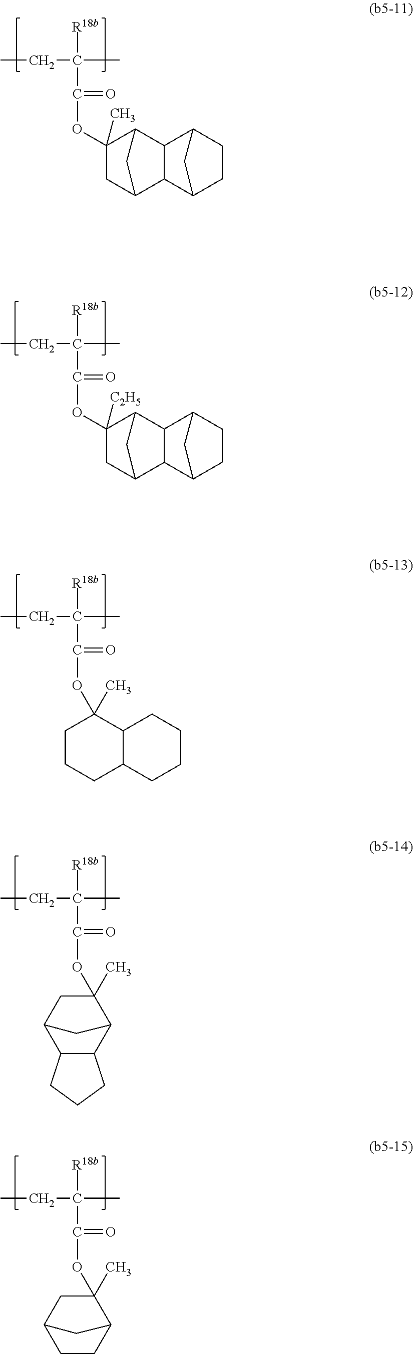

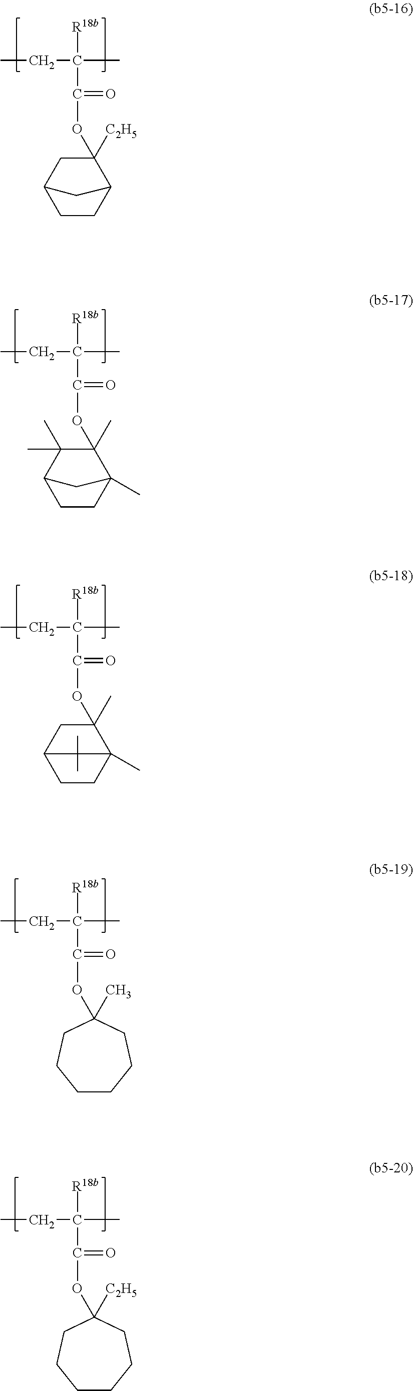

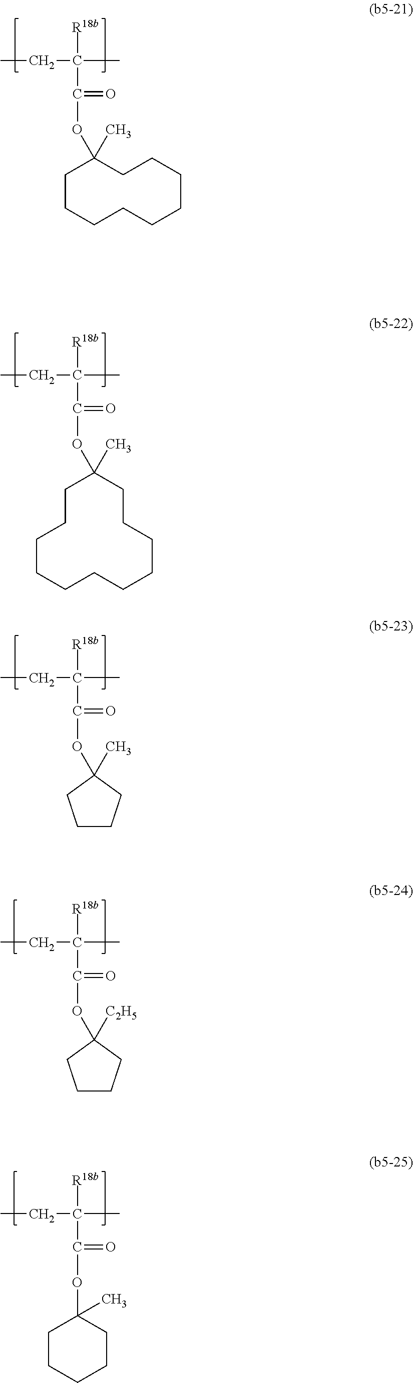

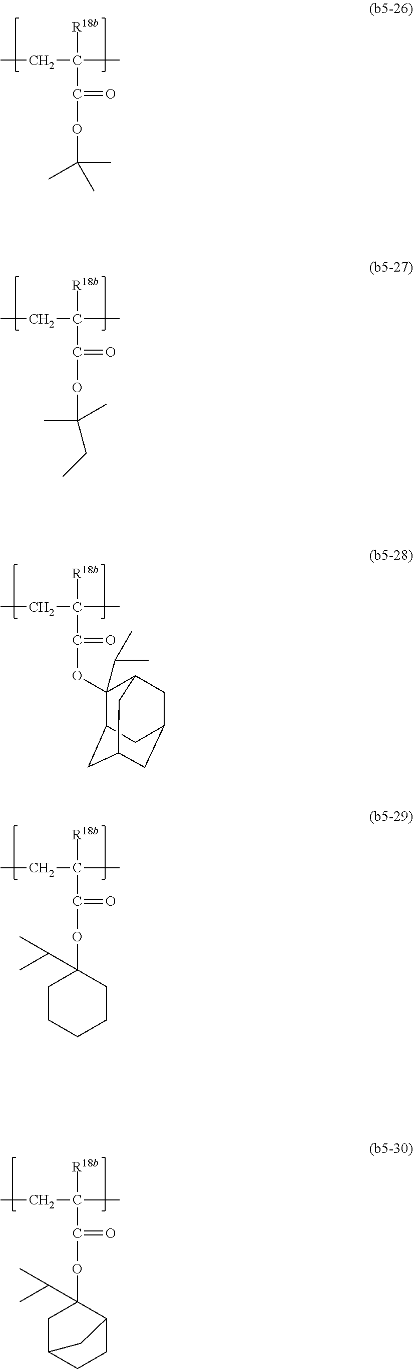

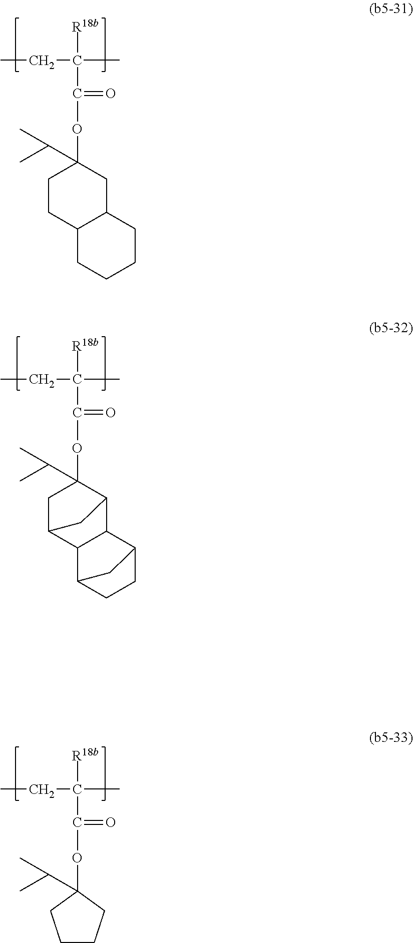

In the above formulae (b5-1) to (b5-33), R^{18b} represents a hydrogen atom or a methyl group.

Preferable specific examples of the structural unit represented by the above general formula (b6) include those represented by the following formulae (b6-1) to (b6-24).

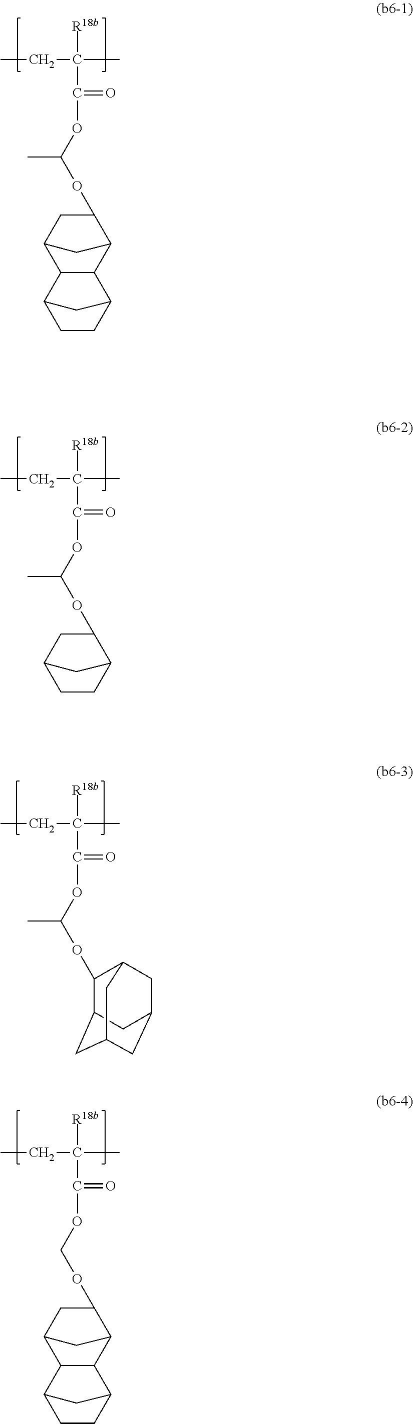

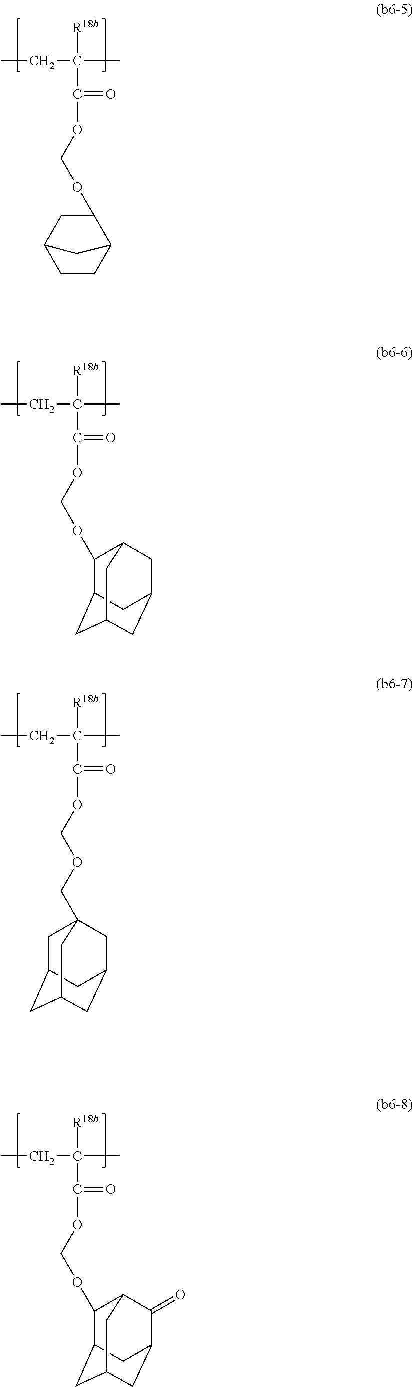

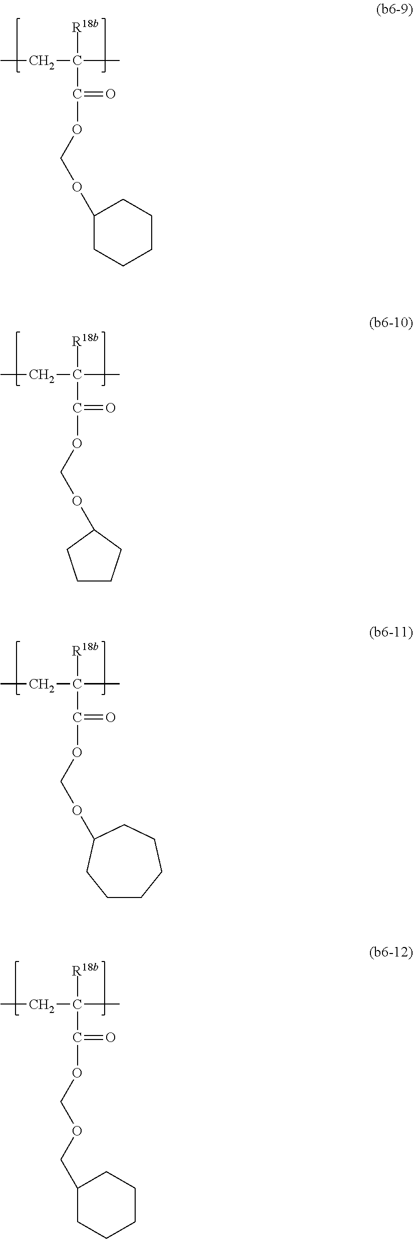

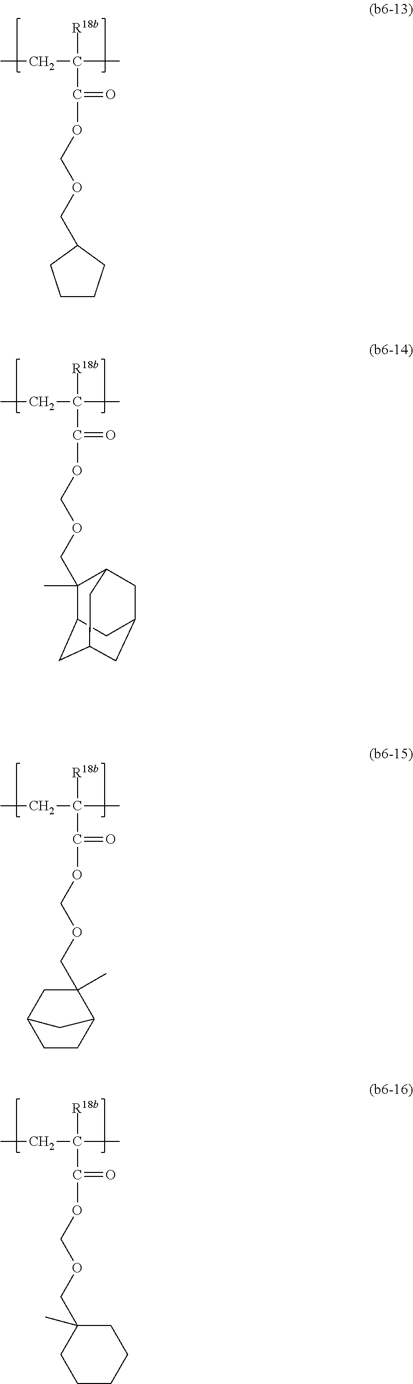

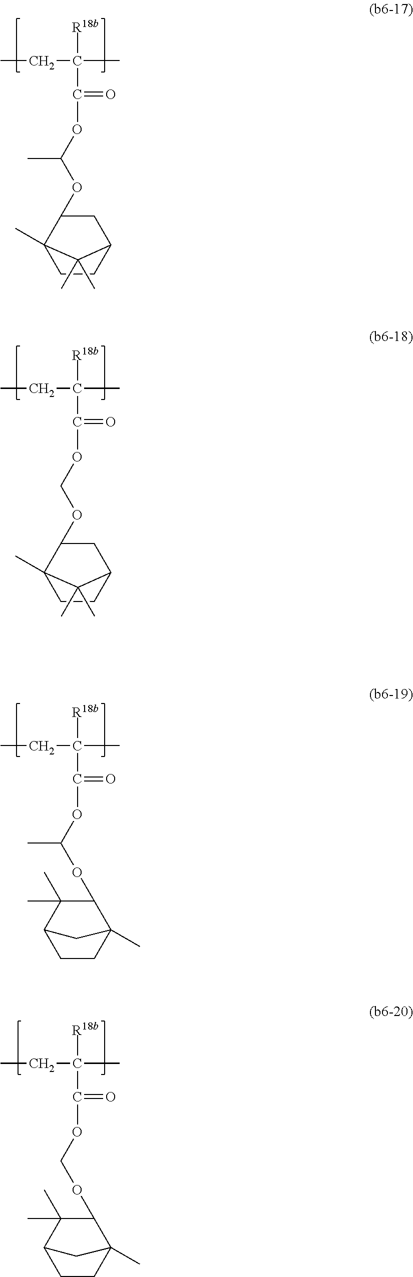

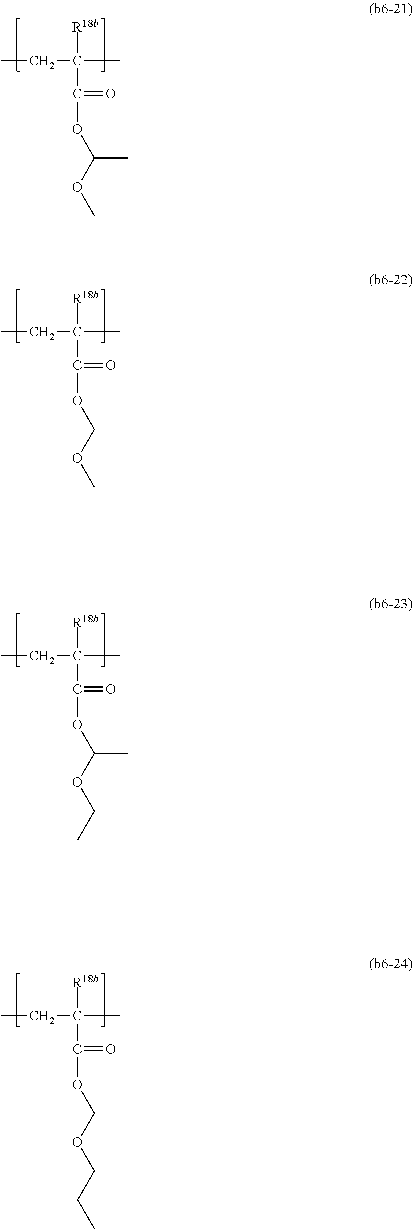

In the above formulae (b6-1) to (b6-24), R^{18b} represents a hydrogen atom or a methyl group.

Preferable specific examples of the structural unit represented by the above general formula (b7) include those represented by the following formulae (b7-1) to (b7-15).

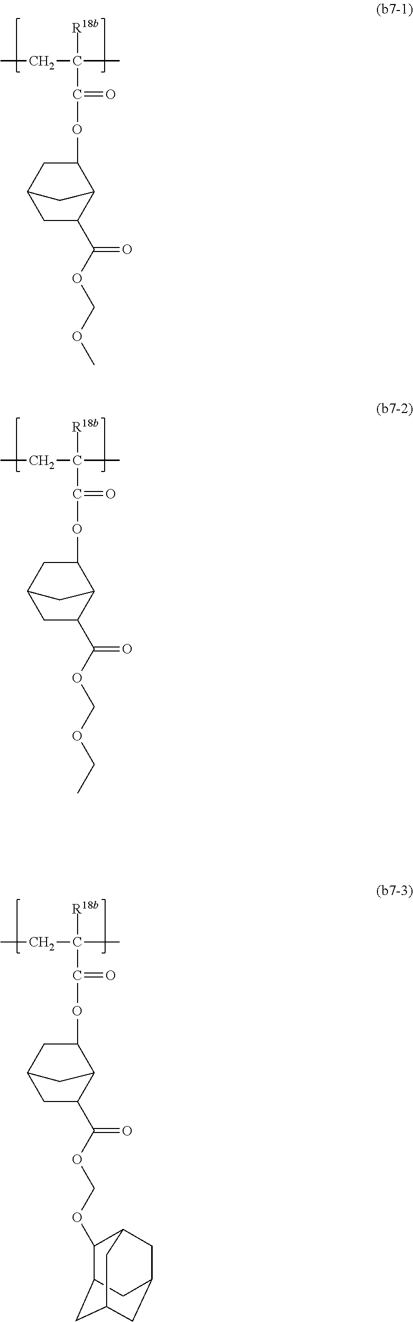

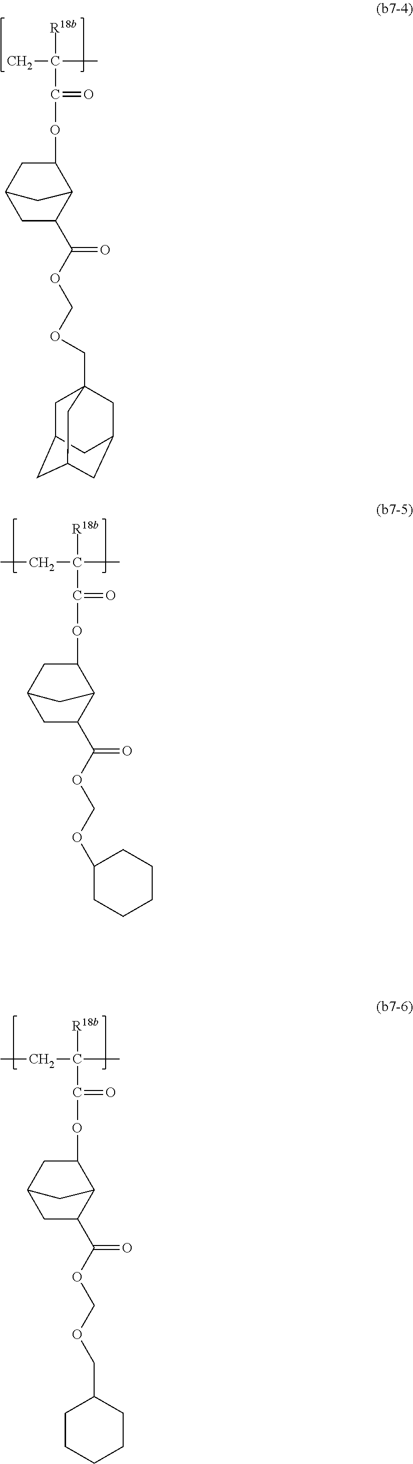

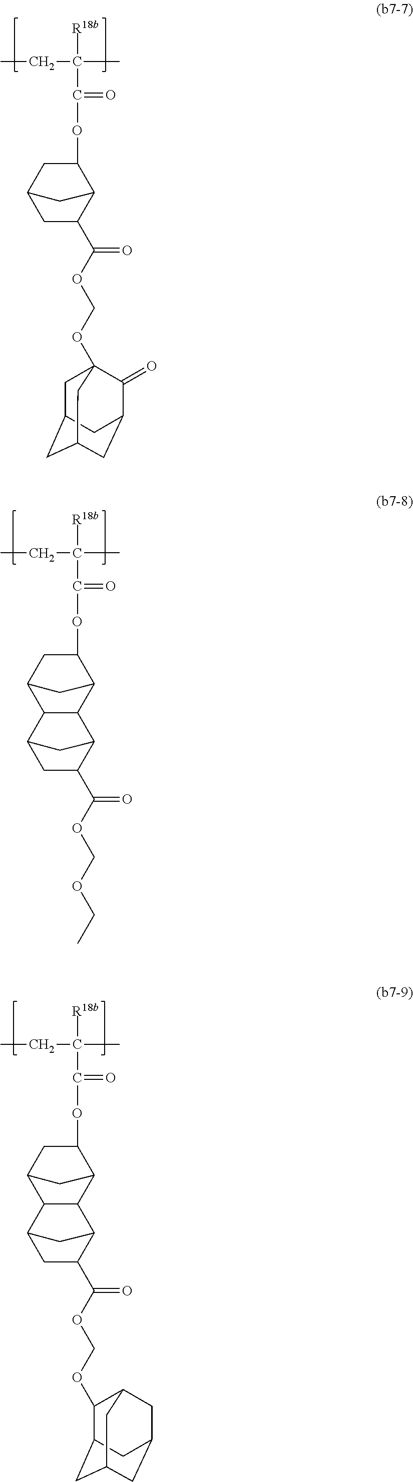

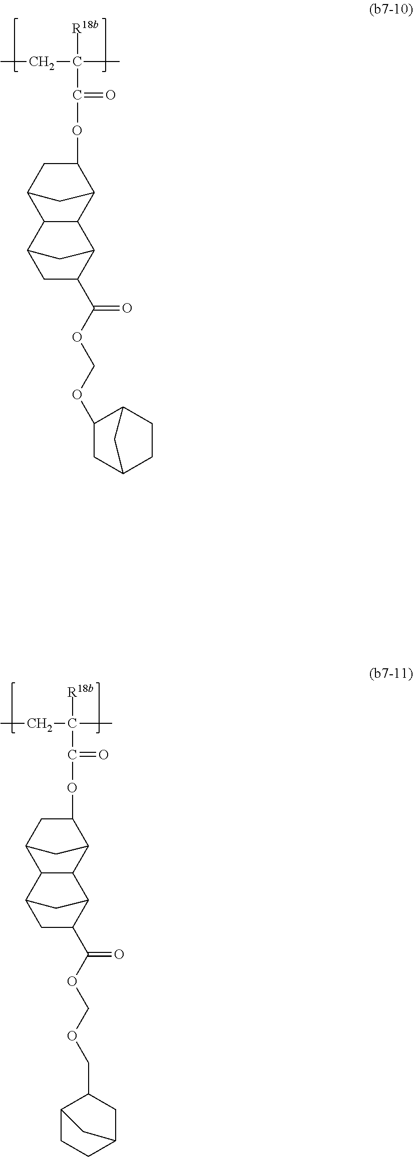

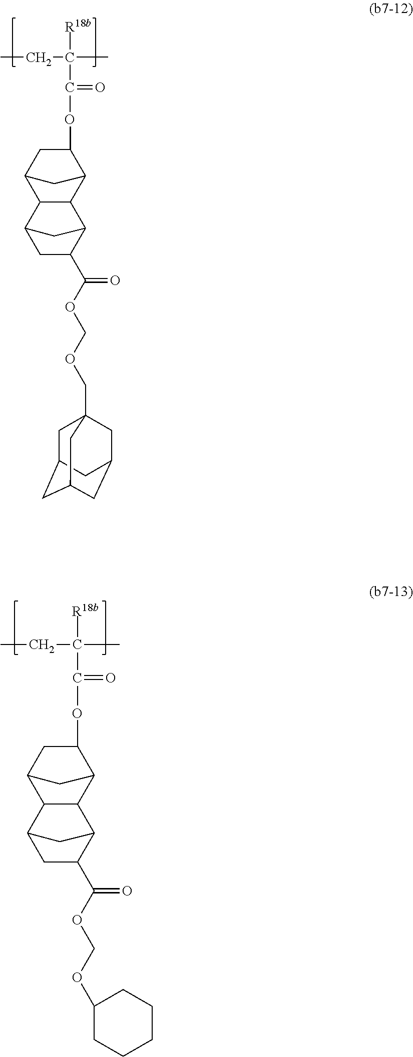

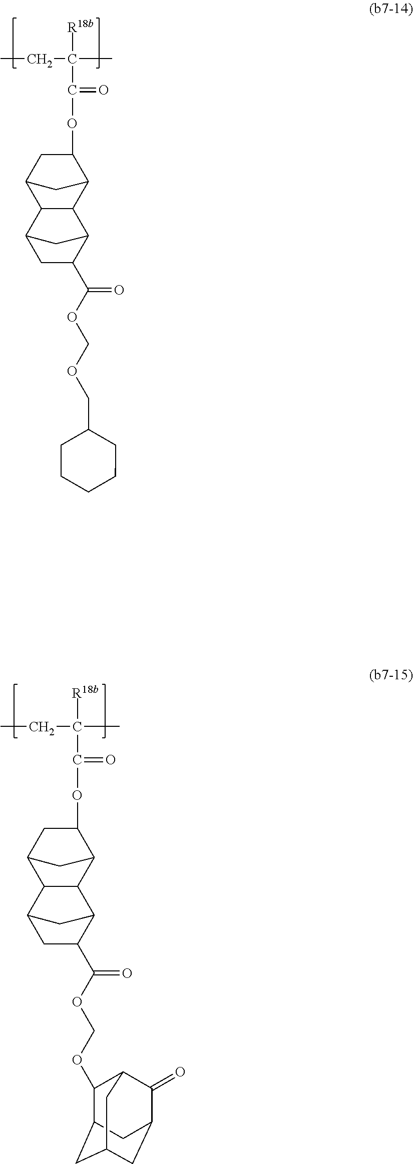

In the above formula (b7-1) to (b7-15), R^{18b} represents a hydrogen atom or a methyl group.

It is also preferred that the acrylic resin (B3) includes a copolymer containing a structural unit derived from a polymerizable compound having an ether bond in addition to the structural unit represented by the above general formulae (b5) to (b7).

Illustrative examples of the polymerizable compound having an ether linkage include radical polymerizable compounds such as (meth)acrylic acid derivatives having an ether linkage and an ester linkage, and specific examples thereof include 2-methoxyethyl(meth)acrylate, 2-ethoxyethyl(meth)acrylate, methoxytriethylene glycol(meth)acrylate, 3-methoxybutyl(meth)acrylate, ethylcarbitol(meth)acrylate, phenoxypolyethylene glycol(meth)acrylate, methoxypolypropylene glycol(meth)acrylate, tetrahydrofurfuryl(meth)acrylate, and the like. Also, the polymerizable compound having an ether linkage is preferably, 2-methoxyethyl(meth)acrylate, 2-ethoxyethyl(meth)acrylate, or methoxytriethylene glycol(meth)acrylate. These polymerizable compounds may be used alone, or in combinations of two or more thereof.

Furthermore, the acrylic resin (B3) may contain another polymerizable compound as a structural unit in order to moderately control physical or chemical properties. The polymerizable compound is exemplified by conventional radical polymerizable compounds and anion polymerizable compounds. Examples of the polymerizable compound include monocarboxylic acids such as acrylic acid, methacrylic acid and crotonic acid; dicarboxylic acids such as maleic acid, fumaric acid and itaconic acid; methacrylic acid derivatives having a carboxyl group and an ester bond such as 2-methacryloyloxyethyl succinic acid, 2-methacryloyloxyethyl maleic acid, 2-methacryloyloxyethyl phthalic acid and 2-methacryloyloxyethyl hexahydrophthalic acid; (meth)acrylic acid alkyl esters such as methyl(meth)acrylate, ethyl(meth)acrylate and butyl(meth)acrylate; (meth)acrylic acid hydroxyalkyl esters such as 2-hydroxyethyl(meth)acrylate and 2-hydroxypropyl(meth)acrylate; (meth)acrylic acid aryl esters such as phenyl(meth)acrylate and benzyl(meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; amide bond-containing polymerizable compounds such as acrylamide and methacrylamide; and the like.

Among the above resins (B), the acrylic resin (B3) is preferably used. It is preferred in particular that the acrylic resin (B3) is a copolymer having a structural unit represented by the above general formula (b5), a structural unit derived from a (meth)acrylic acid, a structural unit derived from a (meth)acrylic acid alkyl ester, and a structural unit derived from a (meth)acrylic acid aryl ester.

The copolymer is preferably one represented by the following general formula (b8).

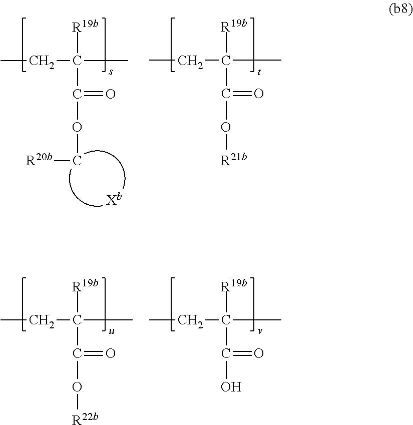

In the above general formula (b8), R^{19b} represents a hydrogen atom or a methyl group; R^{20b} represents a linear or branched alkyl group having 2 to 4 carbon atoms; X^{b} is as defined above; R^{21b} represents a linear or branched alkyl group having 1 to 6 carbon atoms or an alkoxyalkyl group having 1 to 6 carbon atoms; and R^{22b} represents an aryl group having 6 to 12 carbon atoms.

In regard to the copolymers represented by the above general formula (b8), s, t, u and v represent each molar ratio of the structural unit, with s being 8 to 45% by mole, t being 10 to 65% by mole, u being 3 to 25% by mole, and v being 6 to 25% by mole.

The polystyrene equivalent mass average molecular weight of the resin (B) is preferably 10,000 to 600,000, more preferably 10,000 to 300,000, and still more preferably 20,000 to 150,000. By thus adjusting the mass average molecular weight, the thick photoresist layer can maintain sufficient strength without deteriorating peel properties with supports, and also swelling of profiles in plating, and generation of cracks can be prevented.

It is also preferred that the resin (B) has a dispersivity of no less than 1.05. Dispersivity herein indicates a value of a mass average molecular weight divided by a number average molecular weight. A dispersivity in the range described above can avoid problems with respect to stress resistance on intended plating or possible swelling of metal layers resulting from the plating process.

The content of the resin (B) is preferably 5 to 60% by mass with respect to the total mass of the photoresist composition according to the present invention.

### Alkali-Soluble Resin (C)

It is preferred that the photoresist composition according to the present invention further contains an alkali-soluble resin (C) in order to improve crack resistance. The alkali-soluble resin as referred to herein may be determined as follows. A solution of the resin to give a resin concentration of 20% by mass (solvent: propylene glycol monomethyl ether acetate) is used to form a resin film having a film thickness of 1 μm on a substrate, and immersed in an aqueous 2.38% by mass TMAH solution for 1 min. If the resin was dissolved in an amount of no less than 0.01 μm, the resin is defined to be alkali soluble. The alkali-soluble resin (C) is preferably at least one selected from the group consisting of novolak resins (C1), polyhydroxystyrene resins (C2) and acrylic resins (C3).

### [Novolak Resin (C1)]

The novolak resin (C1) may be prepared by addition condensation between, for example, aromatic compounds having a phenolic hydroxy group (hereinafter, merely referred to as “phenols”) and aldehydes in the presence of an acid catalyst.

Examples of the phenols include phenol, o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethyl phenol, 3,4,5-trimethyl phenol, p-phenylphenol, resorcinol, hydroquinone, hydroquinone monomethyl ether, pyrogallol, phloroglycinol, hydroxydiphenyl, bisphenol A, gallic acid, gallic acid ester, α-naphthol, β-naphthol, and the like.

Examples of the aldehydes include formaldehyde, furfural, benzaldehyde, nitrobenzaldehyde, acetaldehyde, and the like.

The catalyst used in the addition condensation reaction, which is not specifically limited, is exemplified by hydrochloric acid, nitric acid, sulfuric acid, formic acid, oxalic acid, acetic acid, etc., in regards to acid catalyst.

The flexibility of the novolak resins can be enhanced still more when o-cresol is used, a hydrogen atom of a hydroxide group in the resins is substituted with other substituents, or bulky aldehydes are used.

Preferably, the novolak resin (C1) has a mass average molecular weight of 1,000 to 50,000.

### [Polyhydroxystyrene Resin (C2)]

The hydroxystyrene compound to constitute the polyhydroxystyrene resin (C2) is exemplified by p-hydroxystyrene, α-methylhydroxystyrene, α-ethylhydroxystyrene, and the like.

Among these, the polyhydroxystyrene resin (C2) is preferably prepared to give a copolymer with a styrene resin. The styrene compound to constitute the styrene resin is exemplified by styrene, chlorostyrene, chloromethylstyrene, vinyltoluene, α-methylstyrene, and the like.

Preferably, the mass average molecular weight of the polyhydroxystyrene resin (C2) is 1,000 to 50,000.

### [Acrylic Resin (C3)]

It is preferred that the acrylic resin (C3) includes a structural unit derived from a polymerizable compound having an ether linkage and a structural unit derived from a polymerizable compound having a carboxyl group.

Illustrative examples of the polymerizable compound having an ether linkage include (meth)acrylic acid derivatives having an ether linkage and an ester linkage such as 2-methoxyethyl(meth)acrylate, methoxytriethylene glycol(meth)acrylate, 3-methoxybutyl(meth)acrylate, ethylcarbitol(meth)acrylate, phenoxypolyethylene glycol(meth)acrylate, methoxypolypropylene glycol(meth)acrylate, tetrahydrofurfuryl(meth)acrylate, and the like. The polymerizable compound having an ether linkage is preferably, 2-methoxyethyl acrylate, and methoxytriethylene glycol acrylate. These polymerizable compounds may be used alone, or in combinations of two or more.

Illustrative examples of the polymerizable compound having a carboxyl group include monocarboxylic acids such as acrylic acid, methacrylic acid and crotonic acid; dicarboxylic acids such as maleic acid, fumaric acid and itaconic acid; compounds having a carboxyl group and an ester linkage such as 2-methacryloyloxyethyl succinic acid, 2-methacryloyloxyethyl maleic acid, 2-methacryloyloxyethyl phthalic acid and 2-methacryloyloxyethyl hexahydrophthalic acid. The polymerizable compound having a carboxyl group is preferably, acrylic acid and methacrylic acid. These polymerizable compounds may be used alone, or in combinations of two or more thereof.

Preferably, the mass average molecular weight of the acrylic resin (C3) is 50,000 to 800,000.

The content of the alkali-soluble resin (C) is preferably 5 to 95 parts by mass, and more preferably 10 to 90 parts by mass with respect to 100 parts by mass of the resin (B). Such a content of the alkali-soluble resin (C) of no less than 5 parts by mass relative to 100 parts by mass of the resin (B) is able to improve crack resistance, while the content of no greater than 95 parts by mass tends to prevent a decrease in film thickness at development.

When the alkali-soluble resin (C) is used, the novolak resin (C1) and the polyhydroxystyrene resin (C2) are preferably used in combination with the acrylic resin (B3). In this case, the rate of the acrylic resin with respect to the total mass of the resin is preferably 5 to 80% by mass, more preferably 10 to 70% by mass, and still more preferably 10 to 35% by mass. Also, the rate of the novolak resin is preferably 5 to 80% by mass, more preferably 20 to 70% by mass, and still more preferably 45 to 65% by mass. Also, the rate of the polyhydroxystyrene resin is preferably 5 to 60% by mass, more preferably 5 to 35% by mass, and still more preferably 5 to 30% by mass. By blending with such rates, the acid generator can be more uniformly dispersed in a thick photoresist layer.

### Acid Diffusion Control Agent (D)

In order to improve the resist pattern configuration, the post exposure stability and the like, it is preferred that the photoresist composition according to the present invention further contains (D) an acid diffusion control agent. The acid diffusion control agent (D) is preferably (D1) a nitrogen-containing compound, and (D2) an organic carboxylic acid, or an oxo acid of phosphorus or a derivative thereof may be further included as needed.

### [Nitrogen-Containing Compound (D1)]

Examples of the nitrogen-containing compound (D1) include trimethylamine, diethylamine, triethylamine, di-n-propylamine, tri-n-propylamine, tribenzylamine, diethanolamine, triethanolamine, n-hexylamine, n-heptylamine, n-octylamine, n-nonylamine, ethylenediamine, N,N,N′,N′-tetramethylethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, formamide, N-methylformamide, N,N-dimethylformamide, acetamide, N-methylacetamide, N,N-dimethylacetamide, propionamide, benzamide, pyrrolidone, N-methylpyrrolidone, methylurea, 1,1-dimethylurea, 1,3-dimethylurea, 1,1,3,3,-tetramethylurea, 1,3-diphenylurea, imidazole, benzimidazole, 4-methylimidazole, 8-oxyquinoline, acridine, purine, pyrrolidine, piperidine, 2,4,6-tri (2-pyridyl)-S-triazine, morpholine, 4-methylmorpholine, piperazine, 1,4-dimethylpiperazine, 1,4-diazabicyclo[2.2.2]octane, and the like. Among these, in particular, alkanolamine such as triethanolamine is preferable. These may be used alone, or in combinations of two or more thereof.

The nitrogen-containing compound (D1) may be used in an amount typically in the range of 0 to 5 parts by mass, and particularly in the range of 0 to 3 parts by mass, with respect to 100 parts by mass of total mass of the resin (B) and the alkali-soluble resin (C).

### [Organic Carboxylic Acid or Oxo Acid of Phosphorus or Derivative Thereof (D2)]

Among the organic carboxylic acid, or the oxo acid of phosphorus or the derivative thereof (D2), specific preferred examples of the organic carboxylic acid include malonic acid, citric acid, malic acid, succinic acid, benzoic acid, salicylic acid and the like, and salicylic acid is particularly preferred.

Examples of the oxo acid of phosphorus or derivatives thereof include phosphoric acid and derivatives such as esters thereof such as, e.g., phosphoric acid, phosphoric acid di-n-butyl ester, and phosphoric acid diphenyl ester; phosphonic acid and derivatives such as esters thereof such as, e.g., phosphonic acid, phosphonic acid dimethyl ester, phosphonic acid di-n-butyl ester, phenylphosphonic acid, phosphonic acid diphenyl ester, and phosphonic acid dibenzyl ester; and phosphinic acid and derivatives such as esters thereof such as, e.g., phosphinic acid and phenylphosphinic acid; and the like. Among these, phosphonic acid is particularly preferred. These may be used alone, or in combinations of two or more thereof.

The organic carboxylic acid, or the oxo acid of phosphorus or the derivative thereof (D2) may be used in an amount typically in the range of 0 to 5 parts by mass, and particularly in the range of 0 to 3 parts by mass, with respect to 100 parts by mass of total mass of the resin (B) and the alkali-soluble resin (C).

Moreover, in order to form a salt to allow for stabilization, the organic carboxylic acid, or the oxo acid of phosphorous or the derivative thereof (D2) is preferably used in an amount equivalent to that of the nitrogen-containing compound (D1).

### Organic Solvent (S)

The photoresist composition according to the present invention preferably contains (S) an organic solvent for adjusting the viscosity. Specific examples of the organic solvent include ketones such as acetone, methyl ethyl ketone, cyclohexanone, methyl isoamyl ketone, and 2-heptanone; polyhydric alcohols and derivatives thereof, like monomethyl ethers, monoethyl ethers, monopropyl ethers, monobutyl ethers and monophenyl ethers, such as ethylene glycol, ethylene glycol monoacetate, diethylene glycol, diethylene glycol monoacetate, propylene glycol, propylene glycol monoacetate, dipropylene glycol and dipropylene glycol monoacetate; cyclic ethers such as dioxane; esters such as ethyl formate, methyl lactate, ethyl lactate, methyl acetate, ethyl acetate, butyl acetate, methyl pyruvate, methyl acetoacetate, ethyl acetoacetate, methyl pyruvate, ethylethoxy acetate, methyl methoxypropionate, ethyl ethoxypropionate, methyl 2-hydroxypropionate, ethyl 2-hydroxypropionate, ethyl 2-hydroxy-2-methylpropionate, methyl 2-hydroxy-3-methylbutanate, 3-methoxybutyl acetate and 3-methyl-3-methoxybutyl acetate; aromatic hydrocarbons such as toluene and xylene; and the like. These may be used alone, or as a mixture of two or more thereof.

The content of the organic solvent (S) preferably falls within the range which enables the solid content of the photoresist composition according to the present invention to be 30 to 55% by mass such that the photoresist layer obtained by a spin coating method or the like has a film thickness of no less than 5 μm.

### Other Components

The photoresist composition according to the present invention may further contain a polyvinyl resin for improving plasticity. Specific examples of the polyvinyl resin include polyvinyl chloride, polystyrene, polyhydroxystyrene, polyvinyl acetate, polyvinylbenzoic acid, polyvinyl methyl ether, polyvinyl ethyl ether, polyvinyl alcohol, polyvinyl pyrrolidone, polyvinyl phenol, and copolymers thereof, and the like. The polyvinyl resin is preferably polyvinyl methyl ether in view of lower glass transition temperatures.

In addition, the photoresist composition according to the present invention may further contain an adhesion auxiliary agent for improving adhesive properties with the support. A functional silane coupling agent is preferred as the adhesion auxiliary agent. The functional silane coupling agent may be exemplified by a silane coupling agent having a reactive substituent such as a carboxyl group, a methacryloyl group, an isocyanate group or an epoxy group, and specific examples of the agent include trimethoxysilylbenzoic acid, γ-methacryloxypropyltrimethoxysilane, vinyltriacetoxysilane, vinyltrimethoxysilane, γ-glycidoxypropyltrimethoxysilane, β-(3,4-epoxycyclohexyl)ethyltrimethoxysilane, and the like.

Also, the photoresist composition according to the present invention may further contain a surfactant for improving coating characteristics, defoaming characteristics, leveling characteristics and the like. Specific examples of the surfactant include commercially available fluorochemical surfactants such as BM-1000 and BM-1100 (both manufactured by B.M-Chemie Co., Ltd.), Megafac F142D, Megafac F172, Megafac F173 and Megafac F183 (all manufactured by Dainippon Ink And Chemicals, Incorporated), Flolade FC-135, Flolade FC-170C, Flolade FC-430 and Flolade FC-431 (all manufactured by Sumitomo 3M Ltd.), Surflon S-112, Surflon S-113, Surflon 5-131, Surflon S-141 and Surflon S-145 (all manufactured by Asahi Glass Co., Ltd.), SH-28PA, SH-190, SH-193, SZ-6032 and SF-8428 (all manufactured by Toray Silicone Co., Ltd.), but not limited thereto.

Additionally, in order to finely adjust the solubility in a developing solution, the photoresist composition according to the present invention may further contain an acid, an acid anhydride, or a solvent having a high boiling point.

Specific examples of the acid and acid anhydride include monocarboxylic acids such as acetic acid, propionic acid, n-butyric acid, isobutyric acid, n-valeric acid, isovaleric acid, benzoic acid, and cinnamic acid; hydroxymonocarboxylic acids such as lactic acid, 2-hydroxybutyric acid, 3-hydroxybutyric acid, salicylic acid, m-hydroxybenzoic acid, p-hydroxybenzoic acid, 2-hydroxycinnamic acid, 3-hydroxycinnamic acid, 4-hydroxycinnamic acid, 5-hydroxyisophthalic acid, and syringic acid; polyvalent carboxylic acids such as oxalic acid, succinic acid, glutaric acid, adipic acid, maleic acid, itaconic acid, hexahydrophthalic acid, phthalic acid, isophthalic acid, terephthalic acid, 1,2-cyclohexanedicarboxylic acid, 1,2,4-cyclohexanetricarboxylic acid, butanetetracarboxylic acid, trimellitic acid, pyromellitic acid, cyclopentanetetracarboxylic acid, butanetetracarboxylic acid, and 1,2,5,8-naphthalenetetracarboxylic acid; acid anhydrides such as itaconic anhydride, succinic anhydride, citraconic anhydride, dodecenylsuccinic anhydride, tricarbanilic anhydride, maleic anhydride, hexahydrophthalic anhydride, methyltetrahydrophthalic anhydride, Himic anhydride, 1,2,3,4-butanetetracarboxylic acid, cyclopentanetetracarboxylic dianhydride, phthalic anhydride, pyromellitic anhydride, trimellitic anhydride, benzophenonetetracarboxylic anhydride, ethylene glycol bis anhydrous trimellitate, and glycerin tris anhydrous trimellitate; and the like.

Furthermore, specific examples of the solvent having a high boiling point include N-methylformamide, N,N-dimethylformamide, N-methylformanilide, N-methylacetamide, N,N-dimethylacetamide, N-methylpyrrolidone, dimethyl sulfoxide, benzyl ethyl ether, dihexyl ether, acetonyl acetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, phenyl cellosolve acetate, and the like.

Moreover, the photoresist composition according to the present invention may further contain a sensitizer for improving the sensitivity.

### Preparation of Photoresist Composition

A method for preparing the photoresist composition according to the present invention may be only mixing and stirring each of the aforementioned components by a conventional method. Each of the aforementioned components may be dispersed and mixed using dispersion equipment such as a dissolver, a homogenizer, or a three-roll mill, if necessary. Thereafter, the mixture may further be filtrated using a mesh, a membrane filter, or the like.

### Method for Producing Thick Film Resist Pattern

The method for producing a thick film resist pattern according to the present invention includes: a laminating step of laminating on a support a thick photoresist layer having a film thickness of no less than 5 μm constituted with the photoresist composition according to the present invention; an exposure step of irradiating the thick photoresist layer with radiation including an electromagnetic wave or particle ray; a development step of developing the thick photoresist layer following the exposure to obtain a thick film resist pattern.

The support is not particularly limited, and conventionally well-known one may be used. Illustrative examples of the support include substrates for electronic parts and those on which a predetermined wiring pattern is produced. This substrate includes a substrate made of metals such as titanium, tantalum, palladium, titanium-tungsten, copper, chrome, iron, aluminum, and the like, and silicon, silicon nitride, and a glass substrate, and the like. As materials for a wiring pattern, copper, solder, chromium, aluminum, nickel, gold, and the like may be used.

First, in the laminating step, the photoresist composition according to the present invention is applied on a support, and the solvent is removed by heating (prebaking) to form a thick photoresist layer. Spin coating processes, slit coating processes, roll coating processes, screen coating processes, applicator processes, etc. can be employed for the application on the support.

The prebaking conditions may vary depending on the constituent of the photoresist composition according to the present invention, the film thickness of the thick photoresist layer, and the like. Usually, the conditions may involve temperatures of 70 to 150° C., preferably 80 to 140° C. for a time period of about 2 to 60 min.

The thick photoresist layer has a film thickness of no less than 5 μm, and preferably in the range of 30 to 80 μm.

Subsequently, in the exposure step, the resultant thick photoresist layer is selectively irradiated (exposed) with a radiation including an electromagnetic wave or particle ray, for example, visible light or an ultraviolet ray having a wavelength of 300 to 500 nm through a mask having a predetermined pattern.

Low pressure mercury lamps, high pressure mercury lamps, super high pressure mercury lamps, metal halide lamps, argon gas lasers, etc. can be used for the light source of the radiation. The radiation may include micro waves, infrared rays, visible lights, ultraviolet rays, X-rays, γ-rays, electron beams, proton beams, neutron beams, ion beams, etc. The irradiation dose of the radiation may vary depending on the constituent of the photoresist composition according to the present invention, the film thickness of the thick photoresist layer, and the like. For example, when an ultra high-pressure mercury lamp is used, the dose may be 100 to 10,000 mJ/cm². The radiation includes a light ray to activate the acid generator (A) in order to generate an acid.

After the exposure, diffusion of the acid is promoted through heating by conventional processes, followed by changing the alkali solubility of the thick film photoresist layer in this exposed region.

Next, in the development step, for example, a certain aqueous alkaline solution is used as a developing solution to dissolve and remove unwanted regions, whereby a predetermined thick film resist pattern is produced.

As the developing solution, an aqueous solution of an alkali such as, for example, sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, 1,8-diazabicyclo[5.4.0]-7-undecene or 1,5-diazabicyclo[4.3.0]-5-nonane can be used. Also, an aqueous solution prepared by adding an adequate amount of a water-soluble organic solvent such as methanol or ethanol, or a surfactant to the aqueous solution of the alkali can be used as the developing solution.

The developing time may vary depending on the constituent of the photoresist composition according to the present invention, the film thickness of the thick photoresist layer, and the like. Usually, the developing time is 1 to 30 min. The method of the development may be any one of a liquid-filling method, a dipping method, a paddle method, a spray developing method, and the like.

After the development, washing with running water for 30 to 90 seconds is followed by drying with an air gun, drying in an oven, or the like.

Connecting terminals such as bumps and metal posts can be formed by embedding conductors such as of metals into resist-free portions (portions being subjected to removal by the developing solution) of the resulting thick film resist pattern by way of plating. The plating process is not particularly limited, and may be selected from various conventional processes. Solder plating, copper plating, gold plating and nickel plating liquids are preferably used for the plating liquid, in particular. The remaining thick film resist patterns are finally eliminated using a stripping liquid, etc. in accordance with a common process.

### EXAMPLES

Examples of the present invention are described below; however, the scope of the invention is not intended to be limited by these examples.

### Examples 1 to 10

As the acid generator (A), compounds (PAG-1 to 10) were provided which include the cationic moiety represented by the above general formula (a1) shown in Table 1 below, and [B(C₆F₅)₄]⁻ as the anionic moiety represented by the above general formula (a2).

TABLE 1

| | | | | compounding |
|---|---|---|---|---|
| | | | | amount |
| | | | | (parts by |
| | R^{1a} | R^{2a} | R^{3a} | mass) |
| PAG-1 | —COCH₃ | —S—Ph—COCH₃ | —S—Ph—COCH₃ | 2.00 |
| PAG-2 | —OCH₃ | —OCH₃ | —OCH₃ | 1.64 |
| PAG-3 | —OCOCH₃ | —OCOCH₃ | —OCOCH₃ | 3.00 |
| PAG-4 | —COCH₃ | —COCH₃ | —COCH₃ | 1.69 |
| PAG-5 | —COCH₃ | —S—Ph—COCH₃ | —COCH₃ | 4.00 |
| PAG-6 | —OCOCH₃ | —S—Ph—OCOCH₃ | —S—Ph—OCOCH₃ | 2.07 |
| PAG-7 | —Ph—COCH₃ | —Ph—COCH₃ | —COCH₃ | 5.00 |
| PAG-8 | —OCO-Ad | —OCO-Ad | —OCO-Ad | 2.28 |
| PAG-9 | —O—CH₂—COO-MAd | —O—CH₂—COO-MAd | —O—CH₂—COO-MAd | 6.00 |
| PAG-10 | —OC₆H₁₃ | —OC₆H₁₃ | —OC₆H₁₃ | 1.94 |

Wherein, the substitution positions of R^{1a} to R^{3a} are all para position. In Table 1, Ph denotes phenylene group, and Ad and Mad denote an adamantyl group and a methyladamantyl group represented by the following formulae, respectively.

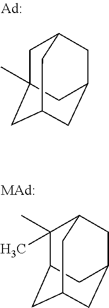

Then, each component shown below was uniformly dissolved in propylene glycol monomethyl ether acetate, and the solution was filtered through a membrane filter having a pore size of 1 μm to prepare a photoresist composition having a solid content of 50% by mass.

Acid Generator (A)

Any one of PAG-1 to 10: compounding amount shown in Table 1 (PAG-1: 2 parts by mass, and PAG-2 to 10: equimolar amount thereof)

Resin (B)

Acrylic resin represented by the following formula (z1) (mass average molecular weight: 40,000, and dispersivity: 1.8): 50 parts by mass

Alkali-Soluble Resin (C)

Novolak resin prepared by addition condensation of m-cresol and p-cresol in the presence of formaldehyde and an acid catalyst: 37 parts by mass

Polyhydroxystyrene Resin (VP-2500: manufactured by Nippon Soda Co., Ltd.): 10 parts by mass

Sensitizer

1,5-dihydroxynaphthalene: 1 part by mass

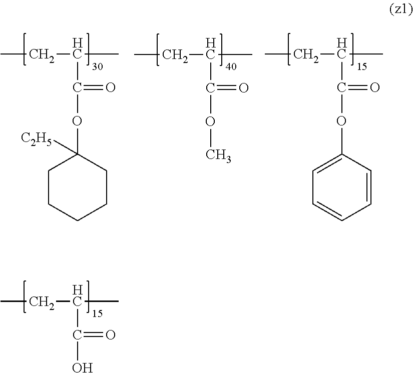

### Comparative Example 1

A photoresist composition was prepared in a similar manner to Examples 1 to 10 except that an equimolar (2.05 parts by mass) compound represented by the following formula (PAG-11) was used as the acid generator (A).

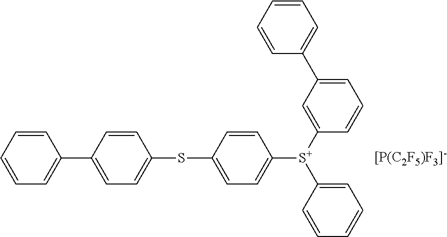

### Comparative Example 2

A photoresist composition was prepared in a similar manner to Examples 1 to 10 except that an equimolar (3.37 parts by mass) compound represented by the following formula (PAG-12) was used as the acid generator (A).

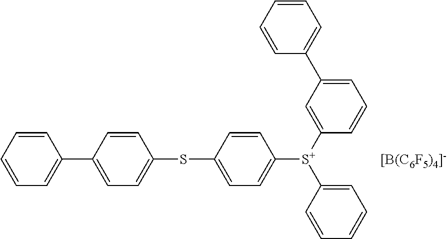

### Comparative Example 3

A photoresist composition was prepared in a similar manner to Examples 1 to 10 except that an equimolar (3.30 parts by mass) compound represented by the following formula (PAG-13) was used as the acid generator (A).

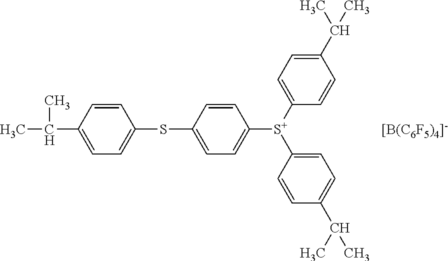

### Comparative Example 4

A photoresist composition was prepared in a similar manner to Example 1 except that: the acrylic resin as the resin (B) was used in an amount of 38.8 parts by mass; 48.5 parts by mass of the novolak resin and 9.7 parts by mass of the polyhydroxystyrene resin were used as the alkali-soluble resin (C), thereby making the rate of the acrylic resin 40% by mass, the rate of the novolak resin 50% by mass and the rate of the polyhydroxystyrene resin 10% by mass with respect to the total mass of the resin; and that a compound represented by the following formula (PAG-14) in an amount of 2.00 parts by mass was used as the acid generator (A).

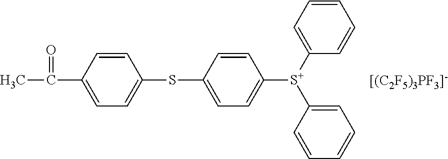

### Comparative Example 5

A photoresist composition was prepared in a similar manner to Comparative Example 4 except that a compound represented by the following formula (PAG-15) in an amount of 2.00 parts by mass was used as the acid generator (A).

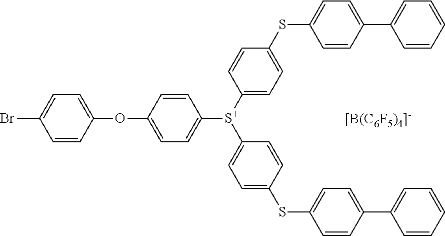

### Evaluation

### [Evaluation of Sensitivity]

The photoresist compositions prepared in Examples 1 to 10, and Comparative Examples 1 to 5 as described above were each applied on an 8-inch copper substrate using a spin coater to form a thick photoresist layer having a film thickness of 50 μm. Then, this thick photoresist layer was prebaked at 140° C. for 5 min. After the prebaking, pattern exposure was carried out with ghi-ray using a mask having a predetermined hole pattern, and a lithography stepper “Prisma GHI” (manufactured by Ultratech, Inc.) while changing the exposure dose stepwise. Next, the substrate was placed on a hot plate, and subjected to post exposure bake (PEB) at 80° C. for 3 min. Thereafter, a 2.38% tetramethylammonium hydroxide (TMAH) aqueous solution was added dropwise onto the thick photoresist layer, and left to stand at 23° C. for 60 sec. These were repeated three times to allow for development. Subsequently, washing with running water and nitrogen blowing were performed to obtain a thick film resist pattern having a contact hole pattern of 60 μm.

Then, the exposure dose with which a pattern residue disappeared, i.e., the minimum exposure dose necessary for producing the thick film resist pattern was determined as a marker of sensitivity. The results are shown in Table 2 below.

### [Evaluation of Resolving Ability]

A thick film resist pattern was produced in a similar manner to that described above in “Evaluation of Sensitivity” except that the mask dimension was changed, and that the exposure dose employed was 1.2 times the minimum exposure dose. Then, the minimum hole diameter that was developable was determined as a marker of resolving ability. The results are shown in Table 2 below.

### [Evaluation of Rectangularity]

A thick film resist pattern was produced in a similar manner to that described above in “Evaluation of Sensitivity” except that the exposure dose employed was 1.2 times the minimum exposure dose. Then, a footing length derived by subtraction of the hole diameter at the bottom of the thick film resist pattern from the hole diameter at the top thereof was determined as a marker of rectangularity. The results are shown in Table 2 below.

### [Evaluation of Controllability of Dimensions]

A thick film resist pattern was produced in a similar manner to that described above in “Evaluation of Sensitivity” except that the exposure dose employed was 1.2 times the minimum exposure dose. Thereafter, a value derived by dividing (hole diameter at the top+hole diameter at the middle+hole diameter at the bottom) by 3 was determined as a hole diameter of the thick film resist pattern, and further the rate (%) of this hole diameter with respect to the mask dimension was determined as a marker of controllability of dimensions. The results are shown in Table 2 below.

TABLE 2

| | | sensitivity | | | |
|---|---|---|---|---|---|
| | acid | (minimum | | rectangularity | controllability of |
| | generator | exposure dose) | resolving ability | (footing length) | dimensions |
| Example 1 | PAG-1 | 750 mJ/cm² | 20 μm | 1.0 μm | 108.0% |
| Example 2 | PAG-2 | 1600 mJ/cm² | 20 μm | 1.6 μm | 110.0% |
| Example 3 | PAG-3 | 1200 mJ/cm² | 20 μm | 1.8 μm | 109.0% |
| Example 4 | PAG-4 | 1150 mJ/cm² | 20 μm | 1.4 μm | 107.2% |
| Example 5 | PAG-5 | 900 mJ/cm² | 20 μm | 1.2 μm | 108.5% |
| Example 6 | PAG-6 | 450 mJ/cm² | 20 μm | 1.3 μm | 106.1% |
| Example 7 | PAG-7 | 900 mJ/cm² | 20 μm | 1.2 μm | 108.5% |
| Example 8 | PAG-8 | 1100 mJ/cm² | 20 μm | 1.7 μm | 105.0% |
| Example 9 | PAG-9 | 1700 mJ/cm² | 20 μm | 1.6 μm | 103.2% |
| Example 10 | PAG-10 | 1800 mJ/cm² | 20 μm | 1.9 μm | 106.1% |
| Comparative | PAG-11 | 600 mJ/cm² | 40 μm | 2.8 μm | 116.0% |
| Example 1 | | | | | |
| Comparative | PAG-12 | 150 mJ/cm² | 20 μm | 2.4 μm | 107.5% |
| Example 2 | | | | | |
| Comparative | PAG-13 | 800 mJ/cm² | 20 μm | 2.7 μm | 107.0% |
| Example 3 | | | | | |
| Comparative | PAG-14 | 900 mJ/cm² | 10 μm | 0.9 μm | 112.4% |
| Example 4 | | | | | |
| Comparative | PAG-15 | 300 mJ/cm² | 10 μm | 0 μm | 121.7% |
| Example 5 | | | | | |

As is seen from Table 2, Examples 1 to 10 in which the acid generator including the cationic moiety represented by the above general formula (a1) and the anionic moiety represented by the above general formula (a2) was used were capable of producing thick film resist patterns having superior resolving ability and controllability of dimensions, and being favorable in rectangularity.

On the other hand, Comparative Example 1 in which the acid generator including a cationic moiety and an anionic moiety both not represented by the above general formulae (a1) and (a2), respectively, was used, exhibited the resolving ability, controllability of dimensions, and rectangularity all inferior to Examples 1 to 10. In addition, Comparative Examples 2 and 3 in which the acid generator including an anionic moiety represented by the above general formula (a2) was used exhibited favorable resolving ability and controllability of dimensions, but inferior rectangularity was exhibited. Furthermore, Comparative Example 4 in which the acid generator including a cationic moiety and an anionic moiety both not represented by the above general formulae (a1) and (a2), respectively, was used; and Comparative Example 5 in which the acid generator including an anionic moiety represented by the above general formula (a2) was used exhibited favorable resolving ability and rectangularity, but inferior controllability of dimensions was exhibited.

### Example 11

A photoresist composition was prepared in a similar manner to Example 1 except that: the acrylic resin as the resin (B) was used in an amount of 48.5 parts by mass; and 38.8 parts by mass of the novolak resin and 19.7 parts by mass of the polyhydroxystyrene resin were used as the alkali-soluble resin (C), thereby making the rate of the acrylic resin 50% by mass, the rate of the novolak resin 40% by mass and the rate of the polyhydroxystyrene resin 10% by mass with respect to the total mass of the resin.

### Example 12

A photoresist composition was prepared in a similar manner to Example 1 except that: the acrylic resin as the resin (B) was used in an amount of 29.1 parts by mass; and 48.5 parts by mass of the novolak resin and 19.4 parts by mass of the polyhydroxystyrene resin were used as the alkali-soluble resin (C), thereby making the rate of the acrylic resin 30% by mass, the rate of the novolak resin 50% by mass and the rate of the polyhydroxystyrene resin 20% by mass with respect to the total mass of the resin.

### Example 13

A photoresist composition was prepared in a similar manner to Example 1 except that: the acrylic resin as the resin (B) was used in an amount of 14.55 parts by mass; and 48.5 parts by mass of the novolak resin and 33.95 parts by mass of the polyhydroxystyrene resin were used as the alkali-soluble resin (C), thereby making the rate of the acrylic resin 15% by mass, the rate of the novolak resin 50% by mass and the rate of the polyhydroxystyrene resin 35% by mass with respect to the total mass of the resin.

### Example 14

A photoresist composition was prepared in a similar manner to Example 1 except that: the acrylic resin as the resin (B) was used in an amount of 29.1 parts by mass; and 58.2 parts by mass of the novolak resin and 9.7 parts by mass of the polyhydroxystyrene resin were used as the alkali-soluble resin (C), thereby making the rate of the acrylic resin 30% by mass, the rate of the novolak resin 60% by mass and the rate of the polyhydroxystyrene resin 10% by mass with respect to the total mass of the resin.

### Example 15

A photoresist composition was prepared in a similar manner to Example 1 except that: the acrylic resin as the resin (B) was used in an amount of 38.8 parts by mass; and 58.2 parts by mass of the novolak resin and 0 parts by mass of the polyhydroxystyrene resin were used as the alkali-soluble resin (C), thereby making the rate of the acrylic resin 40% by mass, the rate of the novolak resin 60% by mass and the rate of the polyhydroxystyrene resin 0% by mass with respect to the total mass of the resin.

### Comparative Example 6

A photoresist composition was prepared in a similar manner to Example 14 except that PAG-12 described above was used as the acid generator (A).

### Evaluation

### [Evaluation of Rectangularity]

The photoresist compositions prepared in Examples 11 to 15, and Comparative Example 6 as described above were each applied on an 8-inch copper substrate using a spin coater to form a thick photoresist layer having a film thickness of 50 μm. Then, this thick photoresist layer was prebaked at 140° C. for 5 min. After the prebaking, pattern exposure was carried out with ghi-ray using a mask having a predetermined hole pattern, and a lithography stepper “Prisma GHI” (manufactured by Ultratech, Inc.) at an exposure dose of 1000 mJ/cm². Next, the substrate was placed on a hot plate, and subjected to post exposure bake (PEB) at 80° C. for 3 min. Thereafter, a 2.38% tetramethylammonium hydroxide (TMAH) aqueous solution was added dropwise onto the thick photoresist layer, and left to stand at 23° C. for 60 sec. These were repeated three times to allow for development. Subsequently, washing with running water and nitrogen blowing were performed to obtain a thick film resist pattern having a contact hole pattern of 60 μm.

Then, a footing length derived by subtraction of the hole diameter at the bottom of the thick film resist pattern from the hole diameter at the top thereof was determined as a marker of rectangularity. The results are shown in Table 3 below.

TABLE 3

| | | | | rectangularity |
|---|---|---|---|---|
| | acrylic | novolak | polyhydroxystyrene | (footing |
| | resin | resin | resin | length) |
| Example 11 | 50% | 40% | 10% | 1.0 μm |
| Example 12 | 30% | 50% | 20% | 0.8 μm |
| Example 13 | 15% | 50% | 35% | 0.9 μm |
| Example 14 | 30% | 60% | 10% | 0.4 μm |
| Example 15 | 40% | 60% | 0% | 0.8 μm |
| Comparative | 30% | 60% | 10% | 1.6 μm |
| Example 6 | | | | |

As is seen from Table 3, Examples 11 to 15 in which the acid generator including the cationic moiety represented by the above general formula (a1) and the anionic moiety represented by the above general formula (a2) was used were capable of producing thick film resist patterns being favorable in rectangularity even if the rates of the acrylic resin, the novolak resin and the polyhydroxystyrene resin were variously changed. Among them, particularly favorable rectangularity was exhibited when the rate of the novolak resin as the alkali-soluble resin (C) was relatively increased.

On the other hand, Comparative Example 6 in which the acid generator including an anionic moiety represented by the above general formula (a2) was used exhibited significantly inferior rectangularity to Example 14 irrespective of the rates of the acrylic resin, the novolak resin and the polyhydroxystyrene resin being the same as the rates in Example 14.

What is claimed is:

1. A chemically amplified positive-type photoresist composition for a thick film used for forming on a support a thick photoresist layer,
the composition comprising (A) an acid generator capable of producing an acid upon irradiation with radiation including an electromagnetic wave or particle ray, and (B) a resin whose alkali solubility increases by the action of an acid, wherein
the acid generator (A) comprises a cationic moiety represented by the following general formula (a1): 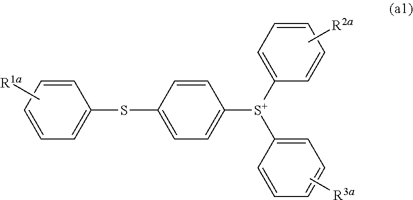
wherein, R^{1a} to R^{3a} each independently represents a group A selected from the group consisting of an alkoxy group, an alkylcarbonyl group, an alkylcarbonyloxy group and an alkyloxycarbonyl group, or a group in which the group A binds to a bivalent linking group,
and an anionic moiety represented by the following general formula (a2): 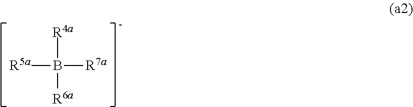
wherein, R^{4a} to R^{7a} each independently represents a fluorine atom or a phenyl group, and a part or all hydrogen atoms of the phenyl group may be substituted with at least one selected from the group consisting of a fluorine atom and a trifluoromethyl group.

2. The chemically amplified positive-type photoresist composition for a thick film according to claim 1, wherein the alkoxy group has 1 to 5 carbon atoms.

3. The chemically amplified positive-type photoresist composition for a thick film according to claim 1, wherein the bivalent linking group is represented by —R^{8a}— or —X—R^{8a}—, wherein, R^{8a} represents a bivalent hydrocarbon group, and X represents a hetero atom.

4. The chemically amplified positive-type photoresist composition for a thick film according to claim 1, wherein the resin (B) comprises at least one resin selected from the group consisting of (B1) a novolak resin, (B2) a polyhydroxystyrene resin, and (B3) an acrylic resin.

5. The chemically amplified positive-type photoresist composition for a thick film according to claim 1, further comprising (C) an alkali-soluble resin.

6. The chemically amplified positive-type photoresist composition for a thick film according to claim 5, wherein the alkali-soluble resin (C) comprises at least one resin selected from the group consisting of (C1) a novolak resin, (C2) a polyhydroxystyrene resin, and (C3) an acrylic resin.

7. The chemically amplified positive-type photoresist composition for a thick film according to claim 5, wherein the resin (B) is (B3) an acrylic resin, and the alkali-soluble resin (C) is (C1) a novolak resin and (C2) a polyhydroxystyrene resin.

8. A method for producing a thick film resist pattern, the method comprising: laminating on a support, a thick photoresist layer having a film thickness of no less than 5 μm constituted with the chemically amplified positive-type photoresist composition for a thick film according to claim 1;
exposing by irradiating the thick photoresist layer with radiation including an electromagnetic wave or particle ray; and
developing the thick photoresist layer following the exposure to obtain a thick film resist pattern.
